(19) United States
(12) Patent Application Publication
(10) Pub. No.: US 2025/0110407 A1
(43) Pub. Date: Apr. 3, 2025

(54) SEMICONDUCTOR SUBSTRATE MANUFACTURING METHOD, AND RESIST BASE FILM FORMING COMPOSITION

(71) Applicant: JSR CORPORATION, Tokyo (JP)

(72) Inventors: Hiroyuki KOMATSU, Tokyo (JP); Masato DOBASHI, Tokyo (JP); Daiki TATSUBO, Tokyo (JP); Sho YOSHINAKA, Tokyo (JP); Shunpei AKITA, Tokyo (JP); Satoshi DEI, Tokyo (JP); Eiji YONEDA, Tokyo (JP); Kengo EHARA, Tokyo (JP)

(73) Assignee: JSR CORPORATION, Tokyo (JP)

(21) Appl. No.: 18/910,163

(22) Filed: Oct. 9, 2024

Related U.S. Application Data
(63) Continuation-in-part of application No. PCT/JP2023/014498, filed on Apr. 10, 2023.

(30) Foreign Application Priority Data
Apr. 13, 2022 (JP) 2022-065964

(51) Int. Cl. G03F 7/039; C08F 220/30; C08F 220/38; C08G 61/12; G03F 7/00; G03F 7/004; G03F 7/038; H01L 21/027

(52) U.S. Cl. CPC G03F 7/0397; C08F 220/303; C08F 220/38; C08G 61/12; C08G 61/122; C08G 61/123; G03F 7/0043; G03F 7/0046; G03F 7/0382; G03F 7/0388; G03F 7/70033; H01L 21/0271

(57) ABSTRACT

A method for manufacturing a semiconductor substrate includes: applying a composition for forming a resist underlayer film directly or indirectly to a substrate to form a resist underlayer film; applying a composition for forming a resist film to the resist underlayer film to form a resist film; exposing the resist film to radiation; and developing at least the exposed resist film. The composition for forming a resist underlayer film includes a polymer and a solvent. The polymer includes a repeating unit (1) which includes an organic sulfonic acid anion moiety and an onium cation moiety.

### CROSS-REFERENCE TO RELATED APPLICATIONS

The present application is a continuation-in-part application of International Patent Application No. PCT/JP2023/014498 filed Apr. 10, 2023, which claims priority to Japanese Patent Application No. 2022-065964 filed Apr. 13, 2022. The contents of these applications are incorporated herein by reference in their entirety.

### BACKGROUND OF THE DISCLOSURE

### Technical Field

The present disclosure relates to a method for manufacturing a semiconductor substrate and a composition for forming a resist underlayer film.

### Background Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate.

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). Various studies have been conducted on compositions for forming a resist underlayer film in such EUV exposure (see WO 2013/141015 A).

### SUMMARY

According to an aspect of the present disclosure, a method for manufacturing a semiconductor substrate includes: applying a composition for forming a resist underlayer film directly or indirectly to a substrate to form a resist underlayer film; applying a composition for forming a resist film to the resist underlayer film to form a resist film; exposing the resist film to radiation; and developing at least the exposed resist film. The composition for forming a resist underlayer film includes a polymer (hereinafter referred to as a “polymer [A]”) and a solvent (hereinafter referred to as a “solvent [C]”). The polymer includes a repeating unit (1) which includes an organic sulfonic acid anion moiety and an onium cation moiety.

According another aspect of the present disclosure, a composition for forming a resist underlayer film includes: a polymer; and a solvent. The polymer includes a repeating unit (1) which includes an organic sulfonic acid anion moiety and an onium cation moiety.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

As the line width of resist patterns formed by exposure to extreme ultraviolet light and development continues to decrease to a level of 20 nm or below, there is a demand for pattern rectangularity that ensures the rectangularity of resist patterns by suppressing the tailing of patterns at the bottom of the resist film.

According to the present embodiments of the method for manufacturing the semiconductor substrate, the semiconductor substrate can be efficiently manufactured because a resist underlayer film forming composition that can form a resist underlayer film with excellent pattern rectangularity is used.

According to the present embodiment of the resist underlayer film forming composition, a film with excellent pattern rectangularity can be formed. Therefore, these can be used suitably for manufacturing semiconductor devices, etc., for which further miniaturization is expected in the future.

Hereinafter, a method for manufacturing a semiconductor substrate and a composition for forming a resist underlayer film according to each embodiment of the present disclosure will be described in detail. Combinations of suitable modes in the embodiments are also preferred.

### <<Method for Manufacturing Semiconductor Substrate>>

The method for manufacturing a semiconductor substrate includes directly or indirectly applying a composition for forming a resist underlayer film to a substrate (this step is hereinafter also referred to as “application step (I)”); applying a composition for forming a resist film to the resist underlayer film formed by applying the composition for forming a resist underlayer film (this step is hereinafter also referred to as “application step (II)”); exposing the resist film formed by applying the composition for forming a resist film to radiation (this step is hereinafter also referred to as “exposure step”); and developing at least the exposed resist film (this step is hereinafter also referred to as “development step”).

By the method for manufacturing a semiconductor substrate, a resist underlayer film superior in pattern rectangularity can be formed due to the use of a prescribed composition for forming a resist underlayer film in the application step (I), so that a semiconductor substrate having a favorable pattern shape can be manufactured.

The method for manufacturing a semiconductor substrate may further include, as necessary, directly or indirectly forming a silicon-containing film on the substrate (this step is hereinafter also referred to as “silicon-containing film formation step”) before the application step (I).

Hereinafter, the composition for forming a resist underlayer film to be used in the method for manufacturing a semiconductor substrate, and the respective steps in the case of including the silicon-containing film formation step, which is an optional step, will be described.

### <Composition for Forming a Resist Underlayer Film>

The composition for forming a resist underlayer film contains a polymer [A], and a solvent [C]. The composition may contain any optional component as long as the effect of the present invention is not impaired. The composition for forming a resist underlayer film can form a resist underlayer film superior in pattern rectangularity owing to containing the polymer [A], and the solvent [C].

### <Polymer [A]>

The polymer [A] contains a repeating unit (1) having an organic sulfonic acid anion moiety and an onium cation moiety. The polymer [A] may have one type or two or more types of the repeating unit (1). The polymer [A] may contain, in addition to the repeating unit (1), a repeating unit having a phenolic hydroxy group or a repeating unit having a group that gives a phenolic hydroxy group by the action of an acid (these are also collectively referred to as “repeating unit (2)”), a repeating unit having an oxazoline structure, an ethylene structure, an ethyne structure, or an oxirane structure (hereinafter, also referred to as “repeating unit (3)”), or the like. The composition may include one type or two or more types of the polymer [A]. The polymer [A] is preferably an acrylic polymer.

### (Repeating Unit (1))

In the repeating unit (1), the organic sulfonic acid anion moiety and the onium cation moiety form an onium salt structure, and an acid (sulfonic acid) is generated through exposure to light. The form of containing the organic sulfonic acid anion moiety and the onium cation moiety is not particularly limited, and the organic sulfonic acid anion moiety may be bonded to the polymer chain of the polymer [A], and the onium cation moiety may be contained as a counter ion thereof, or the onium cation moiety may be bonded to the polymer chain of the polymer [A], and the organic sulfonic acid anion moiety may be contained as a counter ion thereof.

When the polymer [A] is an acrylic polymer, the repeating unit (1) is preferably a repeating unit represented by the following formula (1-1) or (1-2) (hereinafter, each of them is also referred to as “repeating unit (1-1)” or the like).

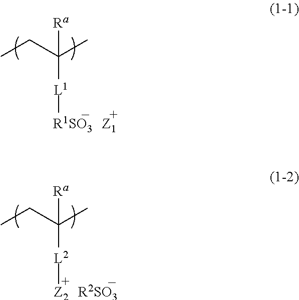

In the formula (1-1), R^{a} is a hydrogen atom or a substituted or unsubstituted monovalent hydrocarbon group having 1 to 20 carbon atoms; L¹ is a divalent linking group; R¹ is a single bond or a divalent organic group having 1 to 40 carbon atoms; and Zit is a monovalent onium cation, in the formula (1-2), R^{a} and L² have the same meanings as R^{a} and L¹ in the formula (1-1), respectively; Z₂+ is a monovalent group having a monovalent onium cation structure; and R² is a monovalent organic group having 1 to 40 carbon atoms.

In the repeating unit (1-1), an organic sulfonic acid anion moiety (—R¹SO₃⁻) is bonded to a polymer chain (side chain) of the polymer [A], and an onium cation moiety (Z₁+) is contained as a counter ion thereof. In the repeating unit (1-2), an onium cation moiety (—Z₂⁺) is bonded to a polymer chain (side chain) of the polymer [A], and an organic sulfonic acid anion moiety (R²SO₃⁻) is contained as a counter ion thereof.

As used herein, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that contains no cyclic structure and is composed only of a chain structure, and includes both a linear hydrocarbon group and a branched hydrocarbon group. The “alicyclic hydrocarbon group” means a hydrocarbon group that contains only an alicyclic structure as a ring structure and contains no aromatic ring structure, and includes both a monocyclic alicyclic hydrocarbon group and a polycyclic alicyclic hydrocarbon group (however, the alicyclic hydrocarbon group is not required to be composed of only an alicyclic structure, and may contain a chain structure as a part thereof). The “aromatic hydrocarbon group” means a hydrocarbon group containing an aromatic ring structure as a ring structure (however, the aromatic hydrocarbon group is not required to be composed of only an aromatic ring structure, and may contain an alicyclic structure or a chain structure as a part thereof).

Examples of the monovalent hydrocarbon group having 1 to 20 carbon atoms represented by R^{a} in the formulas (1-1) and (1-2) include a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon group having 1 to 20 carbon atoms include alkyl groups such as a methyl group, an ethyl group, a n-propyl group, an isopropyl group, a n-butyl group, a sec-butyl group, a tert-butyl group; alkenyl groups such as an ethenyl group, a propenyl group and a butenyl group; and alkynyl groups such as an ethynyl group, a propynyl group and a butynyl group.

Examples of the monovalent alicyclic hydrocarbon group having 3 to 20 carbon atoms include cycloalkyl groups such as a cyclopentyl group and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

When R¹ has a substituent, examples of the substituent include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group, a nitro group, and a hydroxy group.

Among them, a hydrogen atom or a methyl group is preferable as R^{a} from the viewpoint of the copolymerizability of a monomer that affords the repeating unit (1).

In the formulas (1-1) and (1-2), as the divalent linking group represented by L¹ and L², for example, a divalent hydrocarbon group, —COO—, —OCO—, —O—CO—O—, —CONH—, —O—, —S—, —CO—, or a group obtained by combining these groups can be suitably employed.

As the divalent hydrocarbon group as L¹ and L², a group obtained by removing one hydrogen atom from the monovalent hydrocarbon group having 1 to 20 carbon atoms represented by R^{a} can be suitably employed. Among them, L¹ and L² preferably contain a divalent aromatic ring, and more preferably contain a benzenediyl group or a naphthalenediyl group.

Examples of the divalent organic group having 1 to 40 carbon atoms represented by R¹ in the formula (1-1) include groups obtained by removing one hydrogen atom from any of the monovalent organic groups having 1 to 40 carbon atoms represented by R² in the formula (1-2). Therefore, first, the monovalent organic group having 1 to 40 carbon atoms represented by R² in the formula (1-2) will be described. In the present specification, the “organic group” refers to a group containing at least one carbon atom.

Examples of the monovalent organic group having 1 to 40 carbon atoms represented by R² in the formula (1-2) include a monovalent hydrocarbon group having 1 to 40 carbon atoms, a group having a divalent hetero atom-containing group between two adjacent carbon atoms or at a carbon chain end of the foregoing hydrocarbon group, and a group obtained by replacing some or all of the hydrogen atoms of the foregoing hydrocarbon group with a monovalent hetero atom-containing group, and a group obtained by combining them.

As the monovalent hydrocarbon group having 1 to 40 carbon atoms, groups obtained by extending the monovalent hydrocarbon groups having 1 to 20 carbon atoms represented by R^{a} to 40 carbon atoms can be suitably employed.

Examples of the hetero atom that constitutes the divalent or monovalent hetero atom-containing group include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent hetero atom-containing group include —CO—, —CS—, —NR′—, —O—, —S—, —SO₂—, and groups obtained by combining them. R′ is a hydrogen atom or a hydrocarbon group having 1 to 10 carbon atoms.

Examples of the monovalent hetero atom-containing group include a hydroxy group, a sulfanyl group, a cyano group, a nitro group, and halogen atoms.

The organic sulfonic acid anion moiety containing R² is preferably represented by the following formula (p-1). In the formula (p-1), a moiety excluding a sulfonate ion (SO₃−) corresponds to R².

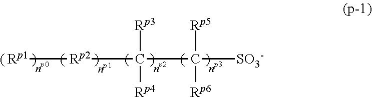

in the formula (p-1), R^{p1} is a monovalent group containing a 5- or higher-membered ring structure;
R^{p2} is a divalent linking group;
R^{p3} and R^{p4} are each independently a hydrogen atom, a fluorine atom, a monovalent hydrocarbon group having 1 to 20 carbon atoms, or a monovalent fluorinated hydrocarbon group having 1 to 20 carbon atoms;
R^{p5} and R^{p6} are each independently a fluorine atom or a monovalent fluorinated hydrocarbon group having 1 to 20 carbon atoms;
n^{p0} is an integer of 0 to 2, n^{p1} is an integer of 0 to 10, n^{p2} is an integer of 0 to 10, and n^{p3} is an integer of 0 to 10, provided that n^{p0}+n^{p1}+n^{p2}+n^{p3} is an integer of 1 or more and 30 or less;
when n^{p1} is 2 or more, the plurality of R^{p2}s are identical or different from each other;
when n^{p2} is 2 or more, the plurality of R^{p3}s are identical or different from each other, and the plurality of R^{p4}s are identical or different from each other;
when n^{p3} is 2 or more, the plurality of R^{p5}s are identical or different, and the plurality of R^{p6}s are identical or different; and
Z⁺ is a monovalent onium cation.

Examples of the monovalent group containing a ring structure represented by R^{p1} include a monovalent group containing an alicyclic structure having 5 or more ring members, a monovalent group containing an aliphatic heterocyclic structure having 5 or more ring members, a monovalent group containing an aromatic ring structure having 6 or more ring members, and a monovalent group containing an aromatic heterocyclic structure having 6 or more ring members.

Examples of the alicyclic structure having 5 or more ring members include:
monocyclic cycloalkane structures such as a cyclopentane structure, a cyclohexane structure, a cycloheptane structure, a cyclooctane structure, a cyclononane structure, a cyclodecane structure, and a cyclododecane structure;
monocyclic cycloalkene structures such as a cyclopentene structure, a cyclohexene structure, a cycloheptene structure, a cyclooctene structure, and a cyclodecene structure;
polycyclic cycloalkane structures such as a norbornane structure, an adamantane structure, a tricyclodecane structure, and a tetracyclododecane structure; and
polycyclic cycloalkene structures such as a norbornene structure and a tricyclodecene structure.

Examples of the aliphatic heterocyclic structure having 5 or more ring members include:
lactone structures such as a pentanolactone structure, a hexanolactone structure, and a norbornane lactone structure;
sultone structures such as a pentanosultone structure, a hexanosultone structure, and a norbornane sultone structure;
oxygen atom-containing heterocyclic structures such as an oxacyclopentane structure, an oxacycloheptane structure, and an oxanorbornane structure;
nitrogen atom-containing heterocyclic structures such as an azacyclopentane structure, an azacyclohexane structure, and a diazabicyclooctane structure; and
sulfur atom-containing heterocyclic structures such as a thiacyclopentane structure, a thiacyclohexane structure, and a thianorbornane structure.

Examples of the aromatic ring structure having 6 or more ring members include a benzene structure, a naphthalene structure, a phenanthrene structure, and an anthracene structure.

Examples of the aromatic heterocyclic structure having 6 or more ring members include oxygen atom-containing heterocyclic structures such as a furan structure, a pyran structure, and a benzopyran structure, and nitrogen atom-containing heterocyclic structures such as a pyridine structure, a pyrimidine structure, and an indole structure.

The lower limit of the number of the ring members of the ring structure of R^{p1} may be 6, and is preferably 7, more preferably 8, still more preferably 9, and particularly preferably 10. The upper limit of the number of the ring members is preferably 15, more preferably 14, still more preferably 13, and particularly preferably 12.

Some or all of the hydrogen atoms which the ring structure of R^{p1} has may be replaced with a substituent. Examples of the substituent include halogen atoms such as a fluorine atom, a chlorine atom, a bromine atom, and an iodine atom, a hydroxy group, a carboxy group, a cyano group, a nitro group, an alkoxy group, an alkoxycarbonyl group, an alkoxycarbonyloxy group, an acyl group, an acyloxy group, and an oxo group (═O). Among them, a hydroxy group and an alkoxy group are preferable.

Among them, monovalent groups containing an alicyclic structure having 5 or more ring members and monovalent groups containing an aliphatic heterocyclic structure having 5 or more ring members are preferable as R^{p1}, monovalent groups containing an alicyclic structure having 6 or more ring members and monovalent groups containing an aliphatic heterocyclic structure having 6 or more ring members are more preferable, monovalent groups containing an alicyclic structure having 9 or more ring members and monovalent groups containing an aliphatic heterocyclic structure having 9 or more ring members are still more preferable, an adamantyl group, a hydroxyadamantyl group, a norbornane lactone-yl group, a norbornane sultone-yl group, and a 5-oxo-4-oxatricyclo[4.3.1.1^{3,8}] undecane-yl group are still more preferable, and an adamantyl group is particularly preferable.

Examples of the divalent linking group represented by R^{p2} include a carbonyl group, an ether group, a carbonyloxy group, a sulfide group, a thiocarbonyl group, a sulfonyl group, a divalent hydrocarbon group, or a combination thereof. As the divalent linking group represented by R^{p2}, a carbonyloxy group, a sulfonyl group, alkanediyl groups, and cycloalkanediyl groups are preferable, a carbonyloxy group and cycloalkanediyl groups are more preferable, a carbonyloxy group and a norbornanediyl group are still more preferable, and a carbonyloxy group is particularly preferable.

Examples of the monovalent hydrocarbon groups having 1 to 20 carbon atoms represented by R^{p3} and R^{p4} include alkyl groups having 1 to 20 carbon atoms. Examples of the monovalent fluorinated hydrocarbon groups having 1 to 20 carbon atoms represented by R^{p3} and R^{p4} include fluorinated alkyl groups having 1 to 20 carbon atoms. As R^{p3} and R^{p4}, a hydrogen atom, a fluorine atom, and fluorinated alkyl groups are preferable, a fluorine atom and perfluoroalkyl groups are more preferable, and a fluorine atom and a trifluoromethyl group are still more preferable.

Examples of the monovalent fluorinated hydrocarbon groups having 1 to 20 carbon atoms represented by R^{p5} and R^{p6} include fluorinated alkyl groups having 1 to 20 carbon atoms. As R^{p5} and R^{p6}, a fluorine atom and fluorinated alkyl groups are preferable, a fluorine atom and perfluoroalkyl groups are more preferable, a fluorine atom and a trifluoromethyl group are still more preferable, and a fluorine atom is particularly preferable.
n^{p0} is preferably 0 or 1.

As n^{p1}, integers of 0 to 5 are preferable, integers of 0 to 3 are more preferable, integers of 0 to 2 are still more preferable, and 0 or 1 is particularly preferable.

As n^{p2}, integers of 0 to 2 are more preferable, 0 or 1 is still more preferable, and 0 is particularly preferable.

As n^{p3}, integers of 0 to 5 are preferable, integers of 1 to 4 are more preferable, integers of 1 to 3 are still more preferable, and 1 or 2 is particularly preferable. By setting n^{p3} to be 1 or more, the strength of the acid generated from the compound of the formula (p-1) can be increased, and as a result, the rectangularity of a resist pattern can be further improved. The upper limit of n^{p3} is preferably 4, more preferably 3, and still more preferably 2.

In the formula (p-1), n^{p0}+n^{p1}+n^{p2}+n^{p3} is an integer of 1 or more and 30 or less. The lower limit of n^{p0}+n^{p1}+n^{p2}+n^{p3} is preferably 2, and more preferably 4. The upper limit of n^{p0}+n^{p1}+n^{p2}+n^{p3} is preferably 20, and more preferably 10.

Examples of the organic sulfonic acid anion moiety containing R represented by the formula (p-1) include structures represented by the following formulas (p-1-1) to (p-1-52).

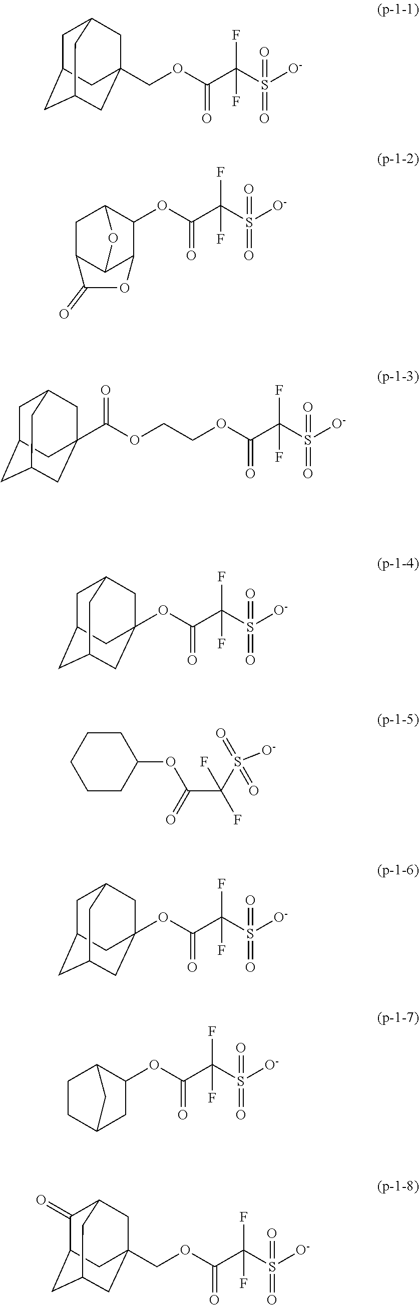

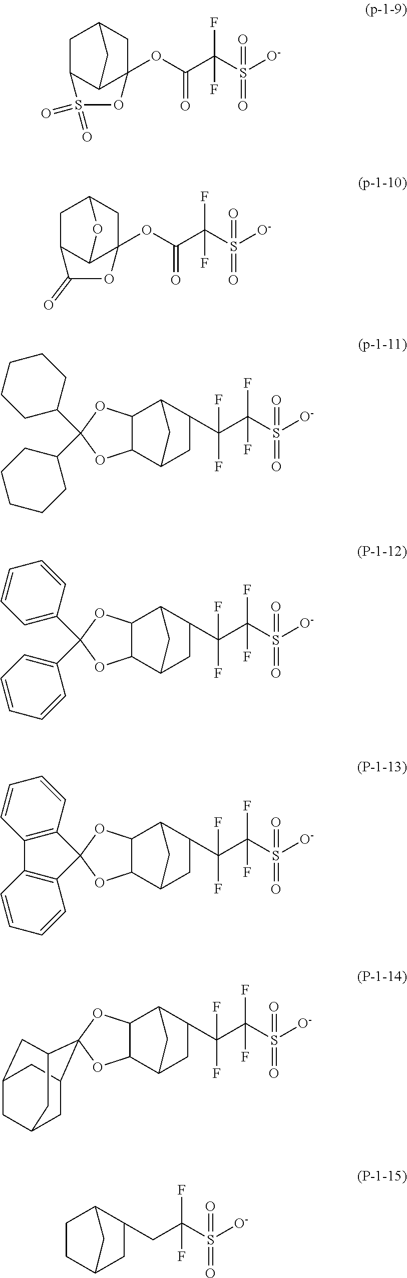

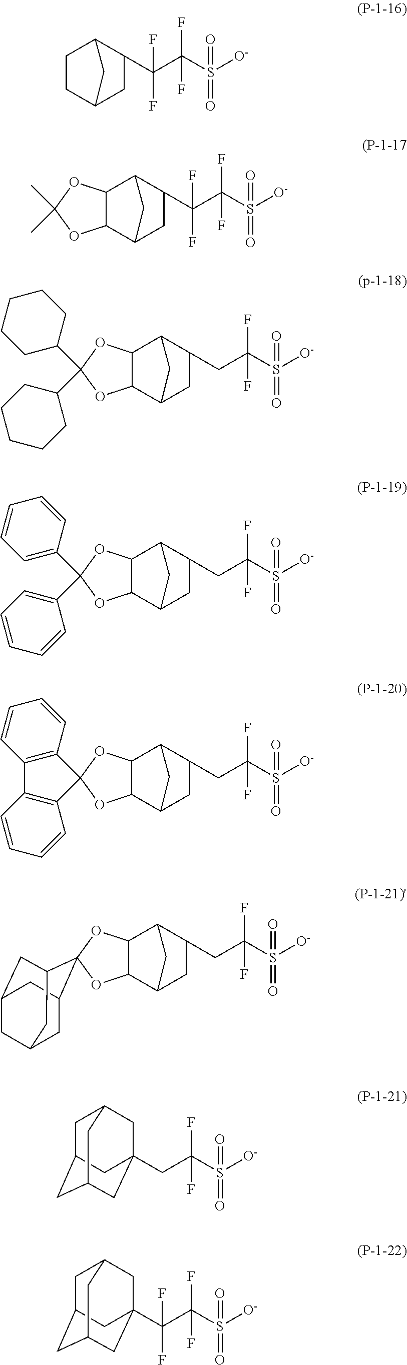

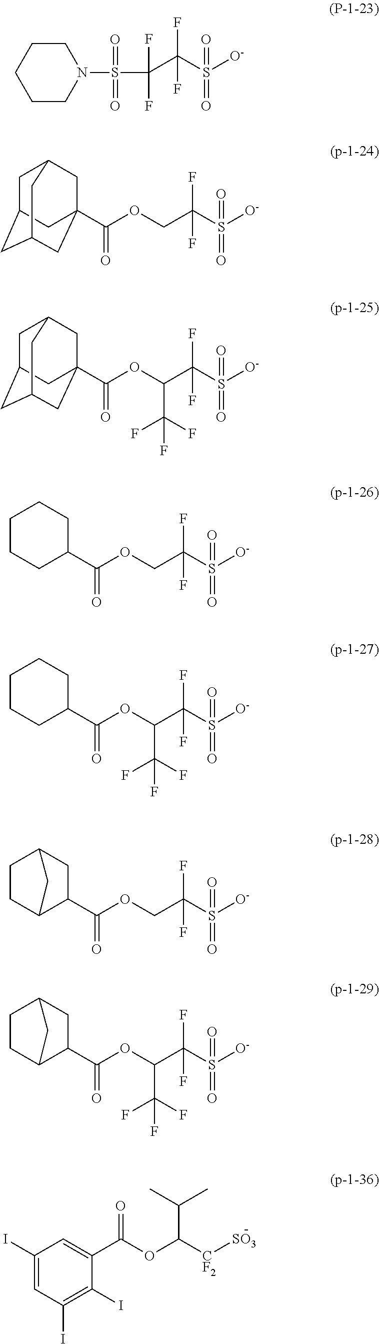

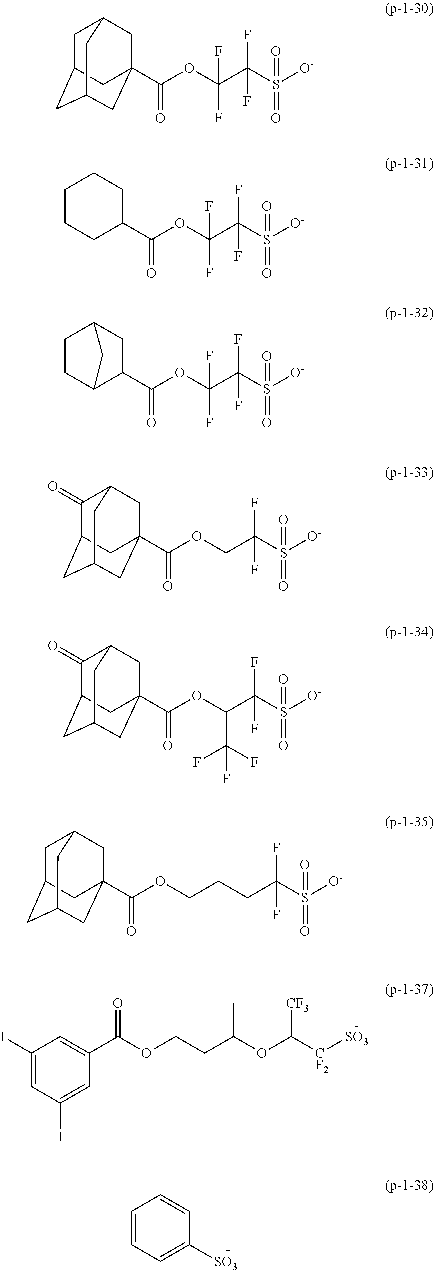

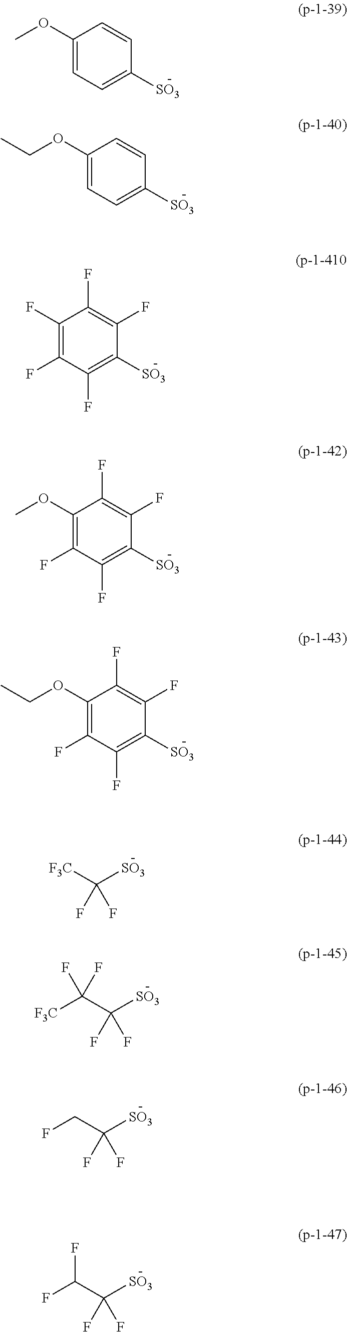

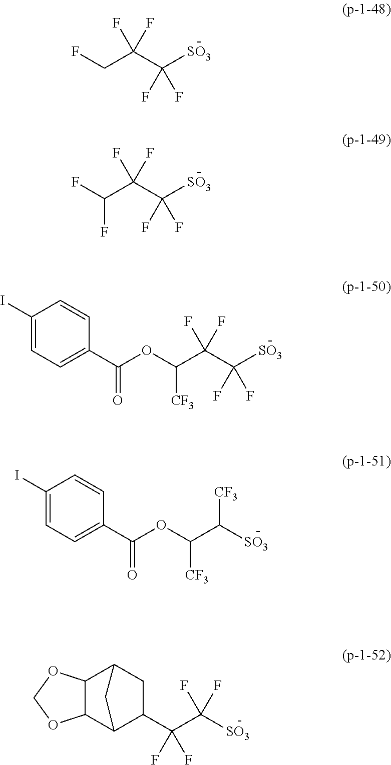

As described above, the divalent organic group having 1 to 40 carbon atoms represented by R¹ in the formula (1-1) corresponds to a structure obtained by removing one hydrogen atom or fluorine atom from the monovalent organic group having 1 to 40 carbon atoms represented by R² in the formula (1-2).

Examples of the monovalent onium cation represented by Zit include radiolytic onium cations containing elements such as S, I, O, N, P, Cl, Br, F, As, Se, Sn, Sb, Te, and Bi, and examples thereof include a sulfonium cation, a tetrahydrothiophenium cation, an iodonium cation, a phosphonium cation, a diazonium cation, and a pyridinium cation. Among these examples, a sulfonium cation or an iodonium cation is preferable. The sulfonium cation or the iodonium cation is preferably represented by the following formulas (X-1) to (X-6).

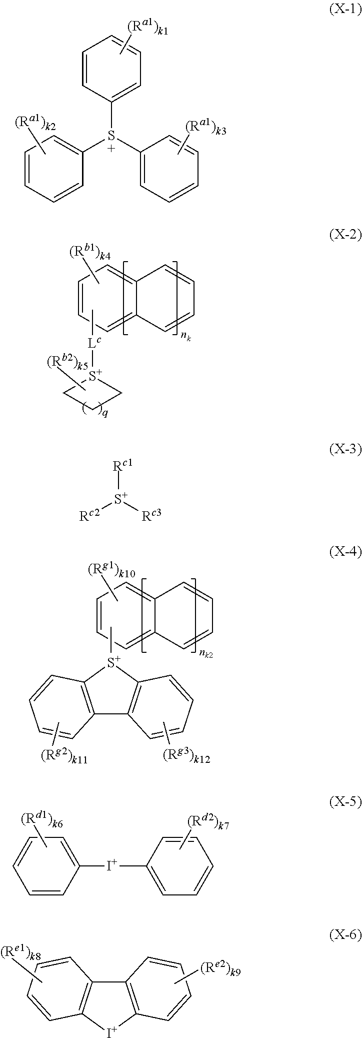

In the formula (X-1), R^{a1}, R^{a2}, and R^{a3} are each independently a substituted or unsubstituted, linear or branched, alkyl, alkoxy, or alkoxycarbonyloxy group having 1 to 12 carbon atoms, a substituted or unsubstituted, monocyclic or polycyclic cycloalkyl group having 3 to 12 carbon atoms, a substituted or unsubstituted aromatic hydrocarbon group having 6 to 12 carbon atoms, a hydroxy group, a halogen atom, —OSO₂—RP, —SO₂—R^{Q}, or —S—R^{T}, or represent a ring structure in which two or more of these groups are combined with each other. The ring structure may contain a hetero atom such as O or S between two adjacent carbon atoms forming the skeleton. R^{P}, R^{Q}, and R^{T} are each independently a substituted or unsubstituted linear or branched alkyl group having 1 to 12 carbon atoms, a substituted or unsubstituted alicyclic hydrocarbon group having 5 to 25 carbon atoms, or a substituted or unsubstituted aromatic hydrocarbon group having 6 to 12 carbon atoms. k1, k2, and k3 are each independently an integer of 0 to 5. When there are pluralities of R^{a1}s to R^{a3}s, R^{P}s, R^{Q}s, and R^{T}s, the pluralities of R^{a1}s to R^{a3}s, R^{P}s, R^{Q}s, and R^{T}s each may be either identical or different.

In the formula (X-2), R^{b1} is a substituted or unsubstituted, linear or branched, alkyl or alkoxy group having 1 to 20 carbon atoms, a substituted or unsubstituted acyl group having 2 to 8 carbon atoms, a substituted or unsubstituted aromatic hydrocarbon group having 6 to 8 carbon atoms, or a hydroxy group. nₖ is 0 or 1. When nₖ is 0, k4 is an integer of 0 to 4, and when nₖ is 1, k4 is an integer of 0 to 7. When there are a plurality of R^{b1}s, the plurality of R^{b1}s may be identical or different, and the plurality of R^{b1} may represent a ring structure constituted by combining them with each other. R^{b2} is a substituted or unsubstituted, linear or branched alkyl group having 1 to 7 carbon atoms or a substituted or unsubstituted aromatic hydrocarbon group having 6 or 7 carbon atoms. L^{C} is a single bond or a divalent linking group. k5 is an integer of 0 to 4. When there are a plurality of R^{b2}s, the plurality of R^{b2}s may be identical or different, and the plurality of R^{b2}s may represent a ring structure constituted by combining them with each other. q is an integer of 0 to 3. In the formula, the ring structure containing S⁺ may contain a hetero atom such as O or S between two adjacent carbon atoms forming the skeleton.

In the above formula (X-3), R^{c1}, R^{c2}, and R^{c3} each independently are substituted or unsubstituted, linear or branched alkyl groups having 1 to 12 carbon atoms.

In the formula (X-4), R^{g1} is a substituted or unsubstituted, linear or branched, alkyl or alkoxy group having 1 to 20 carbon atoms, a substituted or unsubstituted acyl group having 2 to 8 carbon atoms, a substituted or unsubstituted aromatic hydrocarbon group having 6 to 8 carbon atoms, or a hydroxy group. nₖ is 0 or 1. When nₖ₂ is 0, k10 is an integer of 0 to 4, and when nₖ₂ is 1, k10 is an integer of 0 to 7. When there are a plurality of R^{g1}s, the plurality of R^{g1}s may be identical or different, and the plurality of R^{g1} may represent a ring structure constituted by combining them with each other. R^{g2} and R^{g3} are each independently a substituted or unsubstituted, linear or branched, alkyl, alkoxy, or alkoxycarbonyloxy group having 1 to 12 carbon atoms, a substituted or unsubstituted, monocyclic or polycyclic cycloalkyl group having 3 to 12 carbon atoms, a substituted or unsubstituted aromatic hydrocarbon group having 6 to 12 carbon atoms, a hydroxy group, or a halogen atom, or represent a ring structure in which these groups are combined with each other. k11 and k12 are each independently an integer of 0 to 4. When there are pluralities of R^{g2}s and R^{g3}s, the pluralities of R^{g2}s and R^{g3}s may be identical or different, respectively.

In the formula (X-5), R^{d1} and R^{d2} each independently represent a substituted or unsubstituted, linear or branched, alkyl, alkoxy, or alkoxycarbonyl group having 1 to 12 carbon atoms, a substituted or unsubstituted aromatic hydrocarbon group having 6 to 12 carbon atoms, a halogen atom, a halogenated alkyl group having 1 to 4 carbon atoms, or a nitro group, or represent a ring structure constituted by combining two or more of these groups with each other. k6 and k7 each independently are an integer of 0 to 5. When there are pluralities of R^{d1}s and R^{d2}s, the pluralities of R^{d1}s and R^{d2}s may be identical or different, respectively.

In the above formula (X-6), R^{e1} and R^{e2} each independently are a halogen atom, a substituted or unsubstituted linear or branched alkyl group having 1 to 12 carbon atoms, or a substituted or unsubstituted aromatic hydrocarbon group having 6 to 12 carbon atoms. k8 and k9 each independently are an integer of 0 to 4.

Examples of the onium cation include, but not limited thereto, structures represented by the following formulas (i-2-1) to (i-2-47).

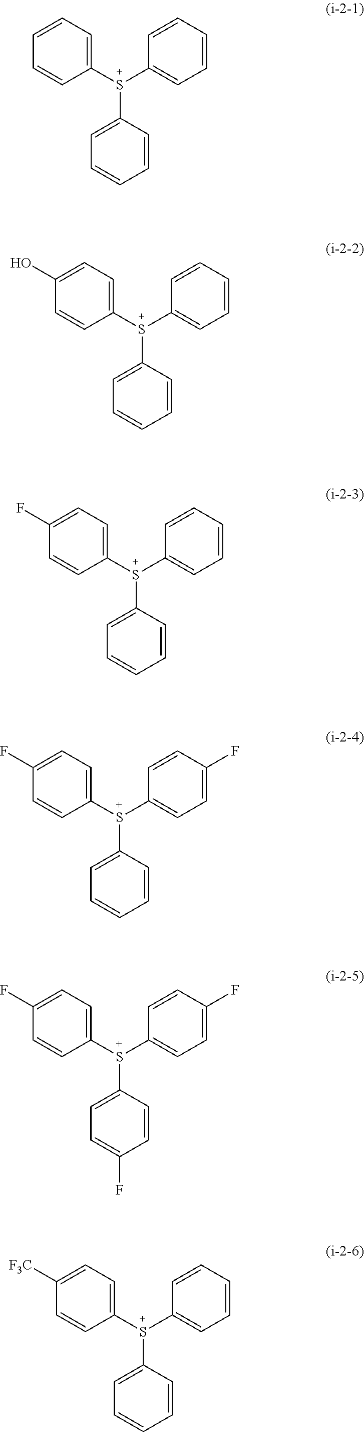

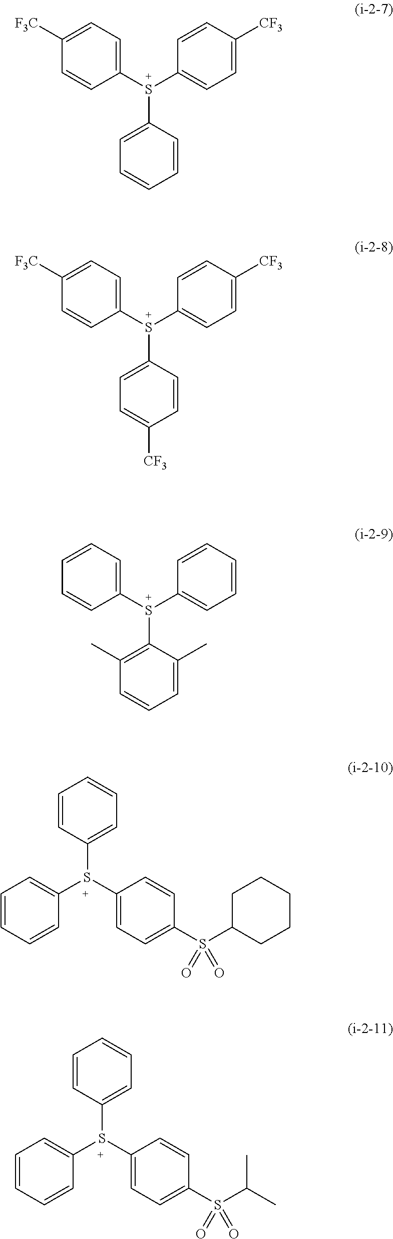

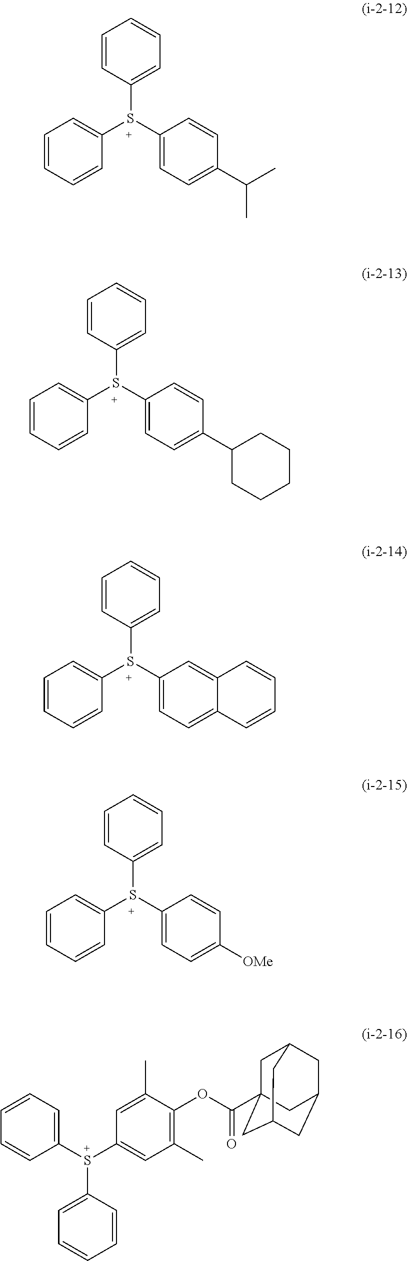

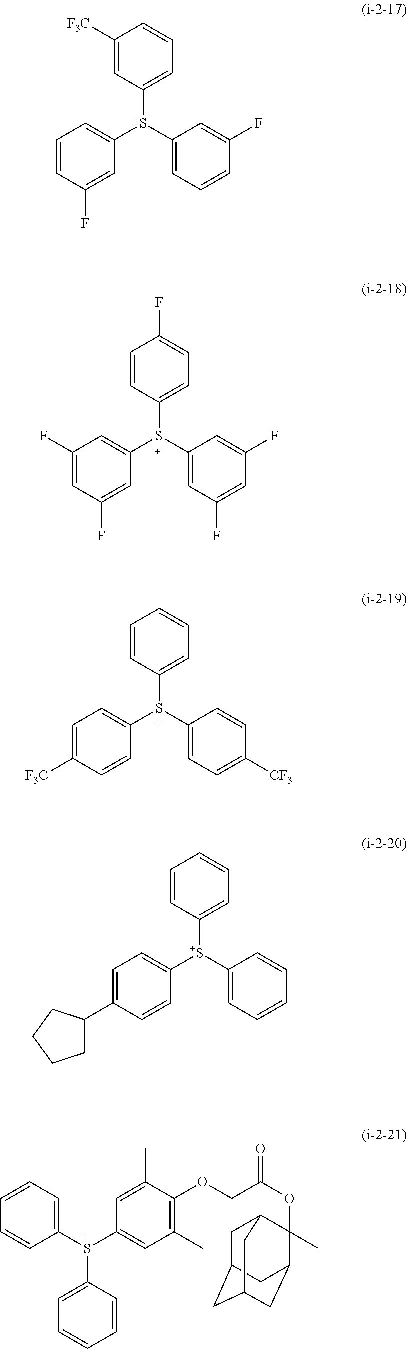

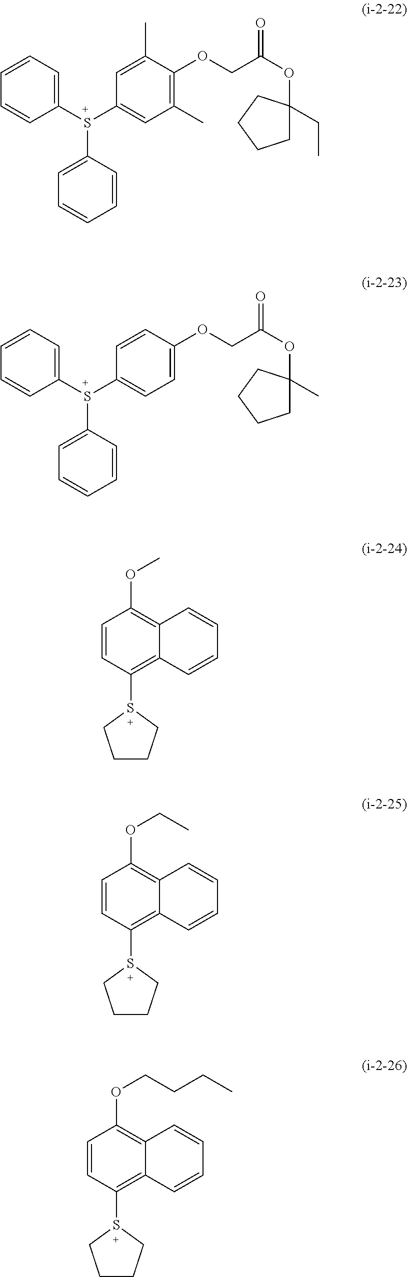

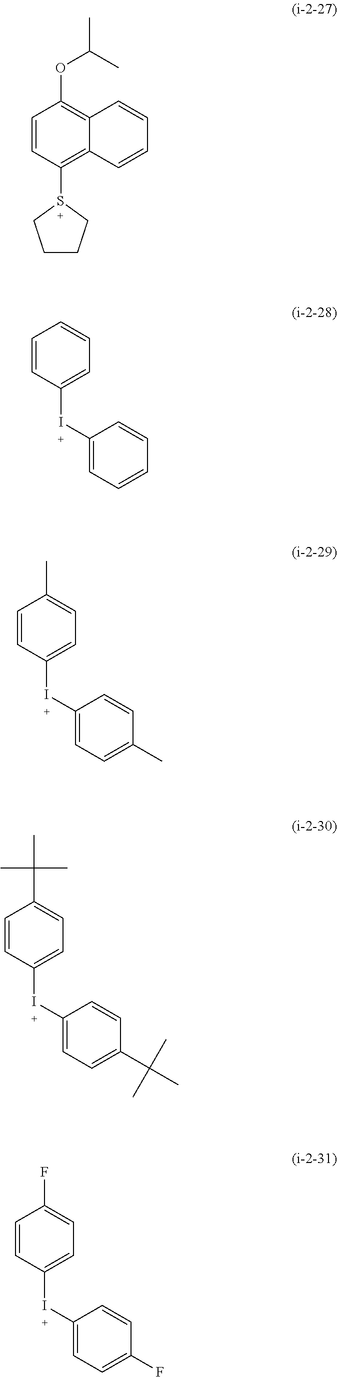

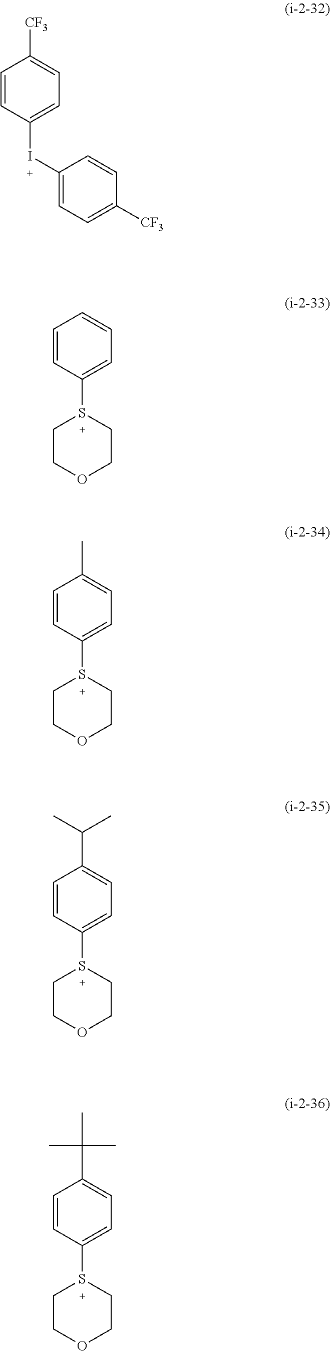

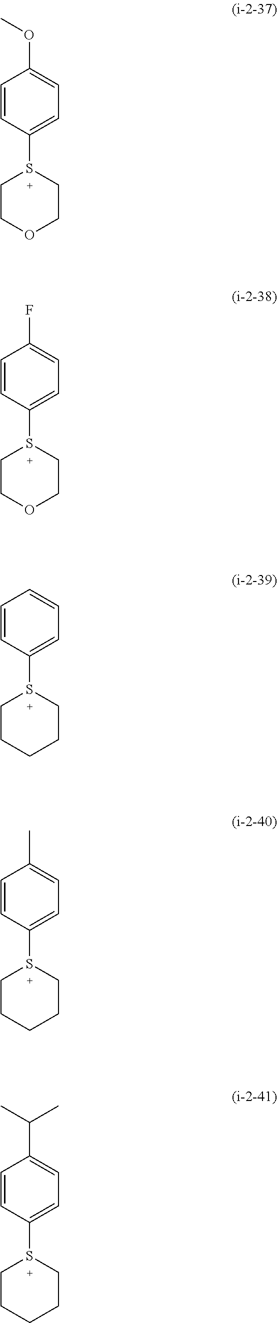

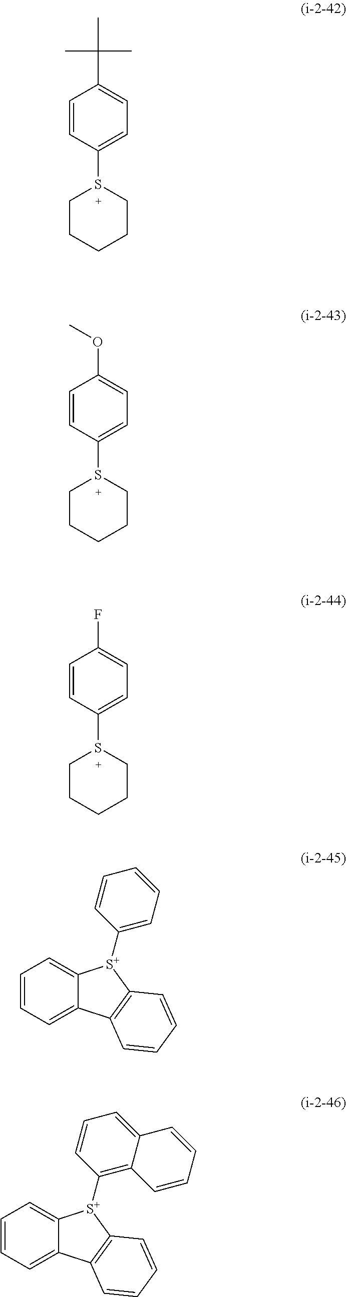

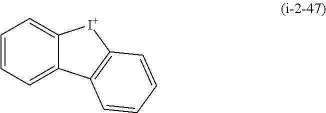 [SMILES: c1ccc2c(c1)[I+]c1ccccc1-2]

Examples of the repeating unit (1-1) include repeating units represented by the following formulas (1-1-1) to (1-1-18).

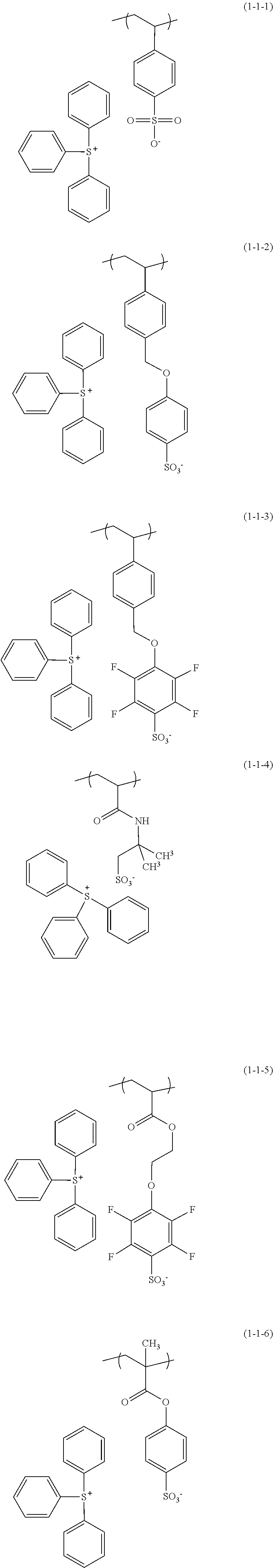

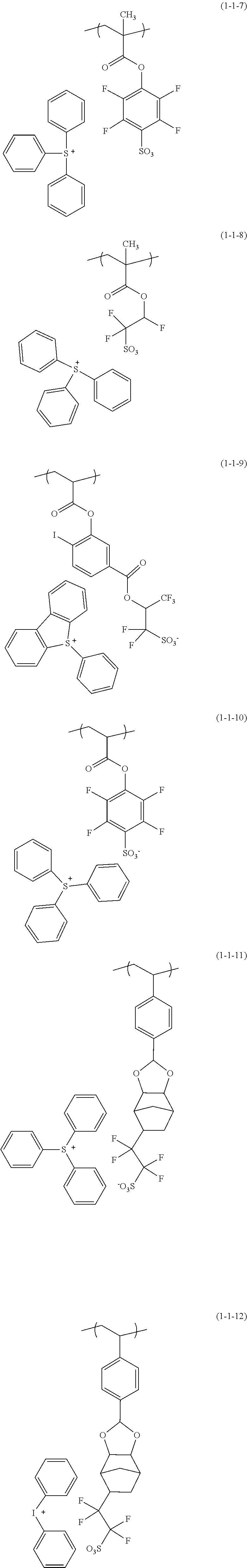

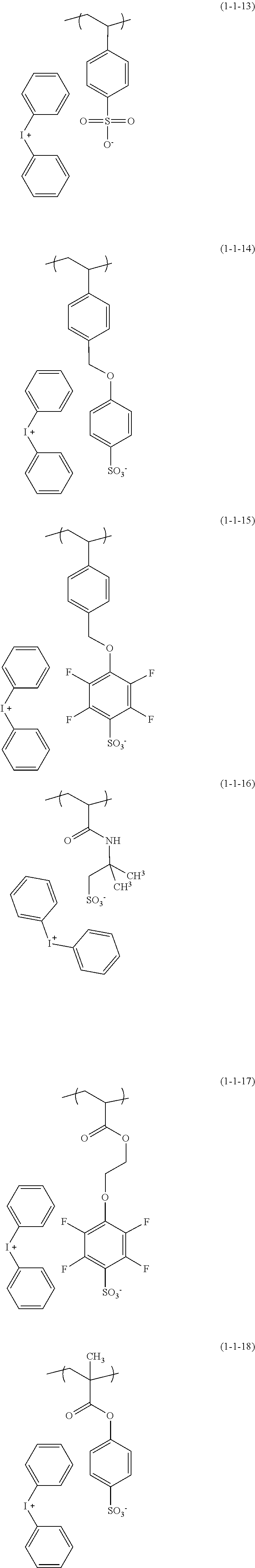

In the formula (1-2), as R^{a} and L², the same groups as R^{a} and L¹ in the formula (1-1) may be employed, respectively.

In the formula (1-2), as the monovalent group having a monovalent onium cation structure represented by Z₂⁺, a group obtained by removing one hydrogen atom from the monovalent onium cation represented by Z₁⁺ in the formula (1-1) can be suitably employed.

The monovalent organic group having 1 to 40 carbon atoms represented by R² is as described above.

Examples of the repeating unit (1-2) include repeating units represented by the following formulas (1-2-1) to (1-2-6). In the following formulas, “TPS” represents triphenylsulfonium.

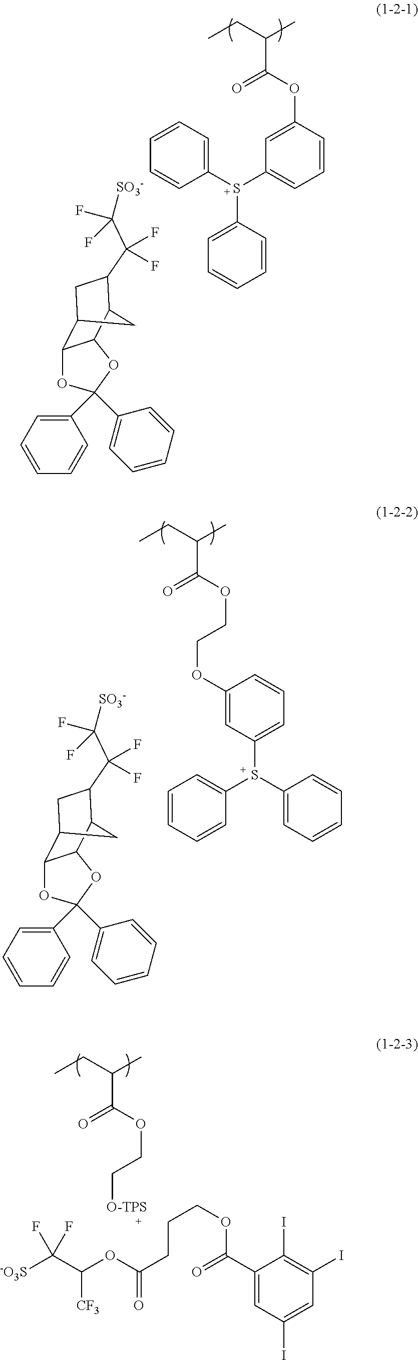

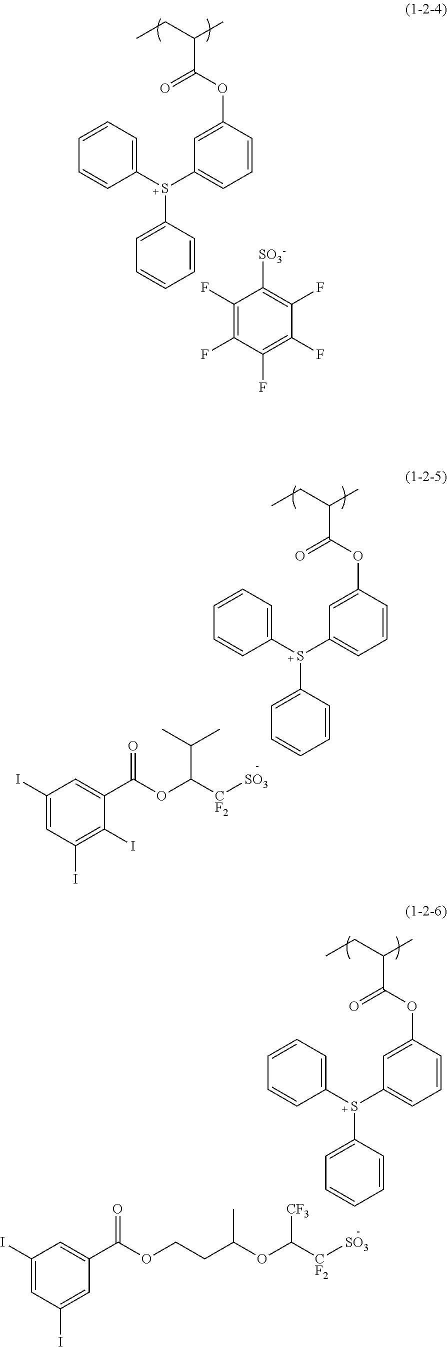

The lower limit of the content ratio of the repeating unit (1) accounting for among all the repeating units constituting the polymer [A] (when there are a plurality of types of the repeating unit (1), the total content ratio is taken) is preferably 5 mol %, more preferably 10 mol %, still more preferably 15 mol %, and particularly preferably 20 mol %. The upper limit of the content ratio is preferably 100 mol %, more preferably 80 mol %, still more preferably 60 mol %, and particularly preferably 40 mol %. When the content ratio of the repeating unit (1) is set within the above range, pattern rectangularity can be exhibited at a high level. Within the above range, when an organic solvent is used as a developer in developing a resist film, a resist underlayer film can be removed together with the resist film.

### (Repeating Unit (2))

The repeating unit (2) is a repeating unit having a phenolic hydroxy group or a repeating unit having a group that affords a phenolic hydroxy group by the action of an acid. In the repeating unit (2), a benzyl alcohol structure is also included in the phenolic hydroxy group. The polymer [A] may have one type or two or more types of the repeating unit (2). When the polymer [A] contains the repeating unit (2), the adhesion of the resist underlayer film to the resist film at the time of exposure to light can be further improved, and pattern rectangularity can be enhanced. In particular, the repeating unit (2) can be suitably applied to pattern formation using exposure with radiation having a wavelength of 50 nm or less such as electron beam or EUV. The repeating unit (2) is preferably represented by the following formula (2).

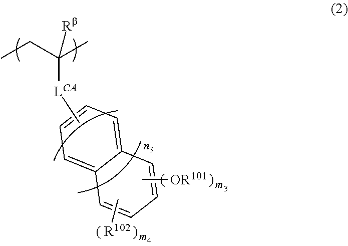

in the formula (2),
R^{β} is a hydrogen atom, a fluorine atom, a methyl group, or a trifluoromethyl group;

L^{CA} is a single bond, —COO—*, or —O—; * is a bond on the aromatic ring side;
R¹⁰¹ is a hydrogen atom or a protective group that is deprotected by the action of an acid; when there is a plurality of R¹⁰¹s, the plurality of R¹⁰¹s are identical or different from each other; when two groups in which R¹⁰¹ and an oxygen atom are combined exist at ortho positions to each other, the two R¹⁰¹s may be bonded to each other to form a dioxolane structure together with the oxygen atoms and carbon atoms of a benzene ring;
R¹⁰² is a cyano group, a nitro group, an alkyl group, a fluorinated alkyl group, a hydroxyalkyl group, an alkoxycarbonyloxy group, an acyl group, or an acyloxy group; when there are a plurality of R¹⁰²'s, the plurality of R¹⁰²'s are identical or different from each other;
n₃ is an integer of 0 to 2, m₃ is an integer of 0 to 8, and m₄ is an integer of 0 to 8, provided that 1≤m₃+m₄≤2n₃+5, and m₃+m₄≥1 are satisfied.

The R^{β} is preferably a hydrogen atom or a methyl group from the viewpoint of the copolymerizability of a monomer that affords the repeating unit (2).

The L^{CA} is preferably a single bond or —COO—*.

Examples of the protecting group that is deprotected due to the action of the acid represented by R¹⁰¹ include groups represented by the following formulas (AL-1) to (AL-5). The formula (AL-5) represents an aspect where a group in which two pairs of R¹⁰¹ and an oxygen atom are combined forms the dioxolane structure.

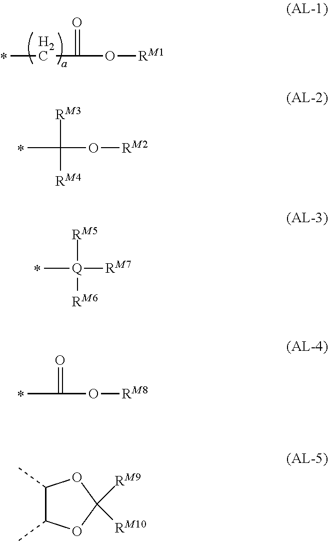

In the formulas (AL-1), (AL-2), and (AL-4), R^{M1}, R^{M2}, and R^{M8} are monovalent hydrocarbon groups, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 40 carbon atoms, and more preferably an alkyl group having 1 to 20 carbon atoms. In the formula (AL-1), a is an integer of 0 to 10, and preferably an integer of 1 to 5. In the formulas (AL-1) to (AL-4), * is a bond to an oxygen atom.

In the formula (AL-2), R^{M3} and R^{M4} are each independently a hydrogen atom or a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{M2}, R^{M3}, and R^{M4} may be bonded to each other to form a ring having 3 to 20 carbon atoms together with the carbon atom or the carbon atom and the oxygen atom to which they are bonded. The ring is preferably a ring having 4 to 16 carbon atoms, and particularly preferably an alicyclic ring.

In the formula (AL-3), Q is a carbon atom or a silicon atom. R^{M5}, R^{M6}, and R^{M7} are each independently a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. Any two of R^{M5}, R^{M6}, and R^{M7} may be bonded to each other to form a ring having 3 to 20 carbon atoms together with the carbon atom to which they are bonded. The ring is preferably a ring having 4 to 16 carbon atoms, and particularly preferably an alicyclic ring.

In the formula (AL-5), R^{M9} and R^{M10} are each independently a hydrogen atom or a monovalent hydrocarbon group, and may contain a hetero atom such as an oxygen atom, a sulfur atom, a nitrogen atom, or a fluorine atom. The monovalent hydrocarbon group may be linear, branched, or cyclic, and is preferably an alkyl group having 1 to 20 carbon atoms. The dashed lines are part of the adjacent aromatic ring with which the dioxolane structure is fused.

Among them, the protective group that is deprotected due to the action of an acid is preferably a group represented by the formula (AL-3).

Examples of the alkyl group as R¹⁰² include linear or branched alkyl groups having 1 to 8 carbon atoms such as a methyl group, an ethyl group, and a propyl group. Examples of the fluorinated alkyl group include linear chain or branched fluorinated alkyl groups having 1 to 8 carbon atoms such as a trifluoromethyl group and a pentafluoroethyl group. Examples of the hydroxyalkyl group include hydroxyalkyl groups having 1 to 10 carbon atoms such as a hydroxymethyl group and a hydroxyethyl group. Examples of the alkoxycarbonyloxy group include chain or alicyclic alkoxycarbonyloxy groups having 2 to 16 carbon atoms such as a methoxycarbonyloxy group, a butoxycarbonyloxy group, and an adamantylmethyloxycarbonyloxy group. Examples of the acyl group include aliphatic or aromatic acyl groups having 2 to 12 carbon atoms such as an acetyl group, a propionyl group, a benzoyl group, and an acryloyl group. Examples of the acyloxy group include aliphatic or aromatic acyloxy groups having 2 to 12 carbon atoms such as an acetyloxy group, a propionyloxy group, a benzoyloxy group, and an acryloyloxy group.

The n₃ is preferably 0 or 1, and more preferably 0.

The m₃ is preferably an integer of 1 to 3, and more preferably 1 or 2.

The m₄ is preferably an integer of 0 to 3, and more preferably an integer of 0 to 2.

As the repeating unit (2), repeating units represented by the following formulas (2-1) to (2-23) (hereinafter, also referred to as “repeating units (2-1) to (2-23)”) and the like are preferable.

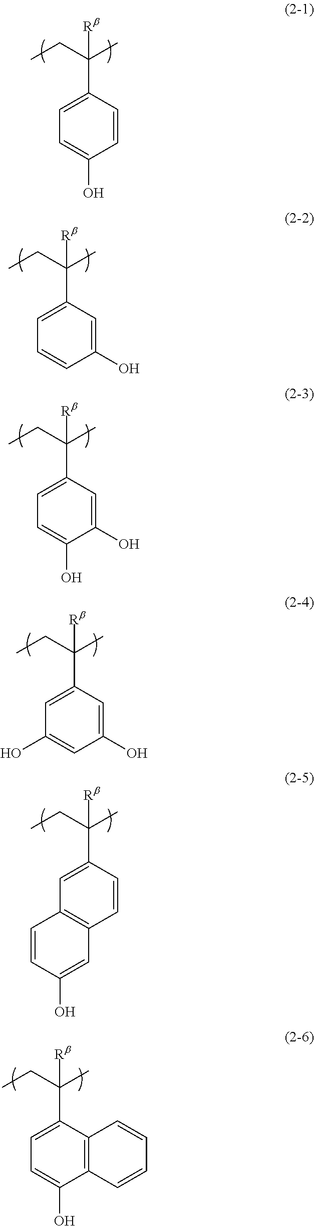

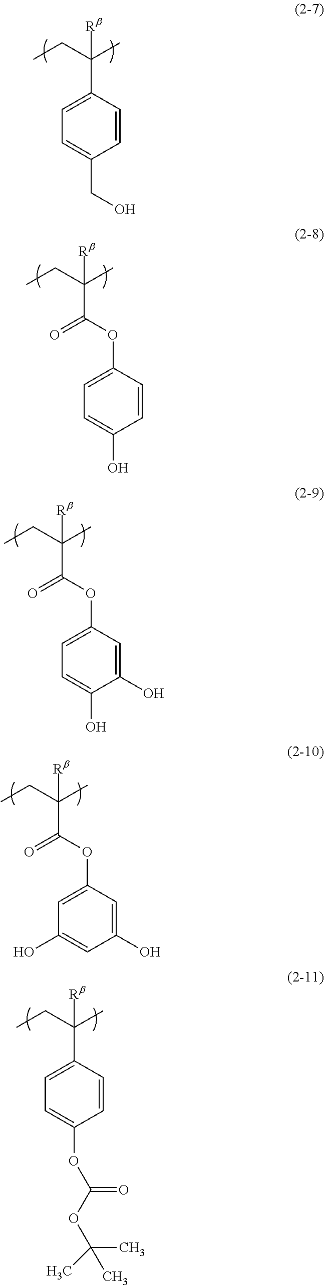

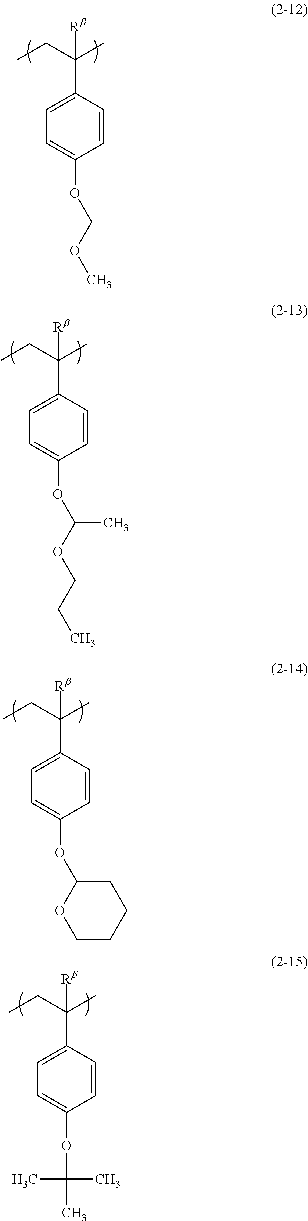

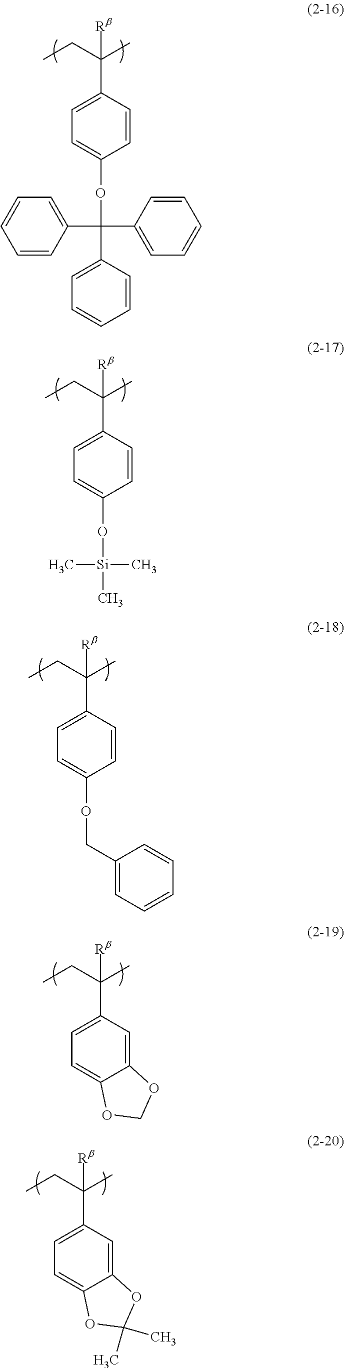

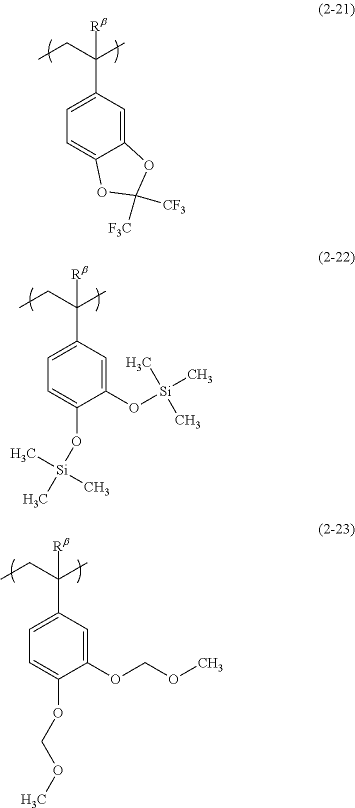

In the formulas (2-1) to (2-23), R^{β} is the same as in the formula (2).

When the polymer [A] contains the repeating unit (2), the lower limit of the content ratio of the repeating unit (2) (when there are a plurality of types of the repeating unit (2), the total content ratio is taken) accounting for among all the repeating units constituting the polymer [A] is preferably 30 mol %, more preferably 40 mol %, still more preferably 50 mol %, and particularly preferably 60 mol %. The upper limit of the content ratio is preferably 95 mol %, more preferably 90 mol %, still more preferably 85 mol %, and particularly preferably 80 mol %. When the content ratio of the repeating unit (2) is set within the above range, pattern rectangularity can be further improved.

When the polymer [A] contains the repeating unit (2) and the R¹⁰¹ is a hydrogen atom, the lower limit of the content ratio of the repeating unit (2) (when there are a plurality of types of the repeating unit (2), the total content ratio is taken) accounting for among all the repeating units constituting the polymer [A] is preferably 1 mol %, more preferably 2 mol %, still more preferably 5 mol %, and particularly preferably 8 mol %. The upper limit of the content ratio is preferably 20 mol %, more preferably 18 mol %, still more preferably 15 mol %, and particularly preferably 12 mol %.

When the polymer [A] contains the repeating unit (2) and the R¹⁰¹ is a group other than a hydrogen atom, the lower limit of the content ratio of the repeating unit (2) (when there are a plurality of types of the repeating unit (2), the total content ratio is taken) accounting for among all the repeating units constituting the polymer [A] is preferably 30 mol %, more preferably 35 mol %, still more preferably 40 mole, and particularly preferably 45 mol %. The upper limit of the content ratio is preferably 85 mol %, more preferably 80 mol %, still more preferably 75 mol %, and particularly preferably 70 mol %.

In the case of polymerizing a monomer having a phenolic hydroxy group such as hydroxystyrene, it is preferable to polymerize the monomer with the phenolic hydroxy group protected by a protecting group such as an alkali-dissociable group and then deprotect it by hydrolysis to obtain a repeating unit (2).

### (Repeating Unit (3))

The repeating unit (3) is a repeating unit having an oxazoline structure, an ethylene structure, an ethyne structure, or an oxirane structure (cases corresponding to either the repeating unit (1) or the repeating unit (2) are excluded). The repeating unit (3) is preferably represented by the following formula (3). The polymer [A] may have one type or two or more types of the repeating unit (3).

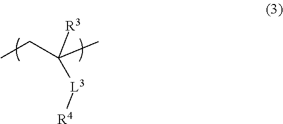

In the formula (3), R³ is a hydrogen atom or a substituted or unsubstituted monovalent hydrocarbon group having 1 to 20 carbon atoms; L³ is a single bond or a divalent linking group; and R⁴ is a monovalent organic group having 1 to 20 carbon atoms and having an oxazoline structure, an ethylene structure, an ethyne structure, or an oxirane structure.

As the monovalent hydrocarbon group having 1 to 20 carbon atoms represented by R³, the groups disclosed as the monovalent hydrocarbon group having 1 to 20 carbon atoms represented by R^{a} in the above formula (1-1) and the like can be suitably employed. When the R³ has a substituent, examples of the substituent include the groups disclosed as the substituent of R^{a} in the formula (1-1).

Examples of the divalent linking group represented by L³ include groups disclosed as the divalent linking group represented by L¹ in the formula (1-1), and L³ is preferably a single bond or —COO—.

Examples of the monovalent organic group having 1 to 20 carbon atoms represented by R⁴ include, among the monovalent organic groups having 1 to 40 carbon atoms represented by R² of the above formula (1-2), organic groups corresponding to 1 to 20 carbon atoms and having an oxazoline structure, an ethylene structure, an ethyne structure, or an oxirane structure in the organic groups.

Examples of the repeating unit (3) include repeating units represented by the following formulas (3-1) to (3-7).

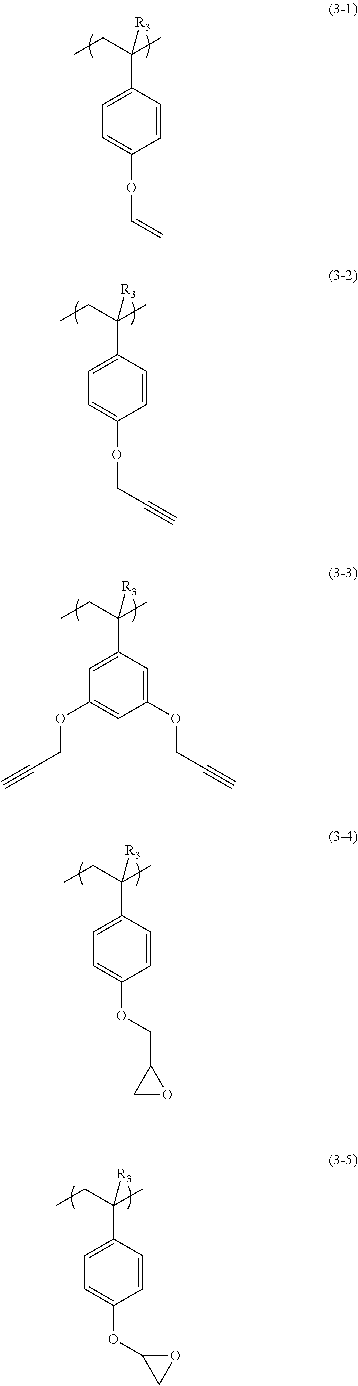

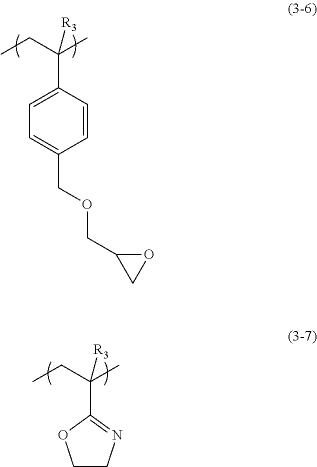

In the formulas (3-1) to (3-7), R³ has the same definition as that in the formula (3).

When the polymer [A] has the repeating unit (3), the lower limit of the content ratio of the repeating unit (3) (when a plurality of types thereof are contained, the total content ratio is taken) accounting for among all the repeating units constituting the polymer [A] is preferably 5 mol %, more preferably 10 mol %, still more preferably 14 mol %, and particularly preferably 16 mol %. The upper limit of the content ratio is preferably 40 mol %, more preferably 30 mol %, still more preferably 25 mol %, and particularly preferably 22 mol %. When the content ratio of the repeating unit (3) is set within the above range, solvent resistance and resist pattern rectangularity can be exhibited at a high level.

The lower limit of the weight average molecular weight of the polymer [A] is preferably 2000, more preferably 4000, still more preferably 5000, and particularly preferably 6000. The upper limit of the molecular weight is preferably 20000, more preferably 15000, still more preferably 12000, and particularly preferably 10000. The weight average molecular weight is measured as described in EXAMPLES.

The lower limit of the content ratio of the polymer [A] in the composition for forming a resist underlayer film is preferably 0.01% by mass, more preferably 0.05% by mass, still more preferably 0.10% by mass, and particularly preferably 0.12% by mass in the total mass of the polymer [A] and the solvent [C]. The upper limit of the content ratio is preferably 3% by mass, more preferably 2% by mass, still more preferably 1% by mass, and particularly preferably 0.5% by mass in the total mass of the polymer [A] and the solvent [C].

The lower limit of the content ratio of the polymer [A] accounting for among the components other than the solvent [C] in the composition for forming a resist underlayer film is preferably 10% by mass, more preferably 20% by mass, still more preferably 30% by mass, and particularly preferably 40% by mass. The upper limit of the content ratio may be 100% by mass, and is preferably 95% by mass, more preferably 90% by mass, still more preferably 85% by mass, and particularly preferably 80% by mass.

### [Method for Synthesizing Polymer [A]]

The polymer [A] can be synthesized by performing radical polymerization, ion polymerization, polycondensation, polyaddition, addition condensation, or the like depending on the type of the monomer. For example, when the polymer [A] is synthesized by radical polymerization, the polymer can be synthesized by polymerizing monomers which will afford respective repeating units using a radical polymerization initiator of the like in an appropriate solvent.

Examples of the radical polymerization initiator include azo radical initiators, such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile) and dimethyl 2,2′-azobisisobutyrate; and peroxide radical initiators, such as benzoyl peroxide, t-butyl hydroperoxide and cumene hydroperoxide. These radical initiators may be used singly, or two or more of them may be used in combination.

As the solvent to be used for the polymerization, the solvent [C] described later can be suitably employed. The solvents to be used for the polymerization may be used singly, or two or more solvents may be used in combination.

The reaction temperature in the polymerization is usually 40° C. to 150° C., and preferably 50° C. to 120° C. The reaction time is usually 1 hour to 48 hours, and preferably 1 hour to 24 hours.

### <Solvent [C]>

The solvent [C] is not particularly limited as long as it can dissolve or disperse the compound [A], and optional components contained as necessary.

Examples of the solvent [C] include a hydrocarbon-based solvent, an ester-based solvent, an alcohol-based solvent, a ketone-based solvent, an ether-based solvent, and a nitrogen-containing solvent. The solvent [C] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as γ-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, and n-propanol, 4-methyl-2-pentanol, and polyhydric alcohol-based solvents such as ethylene glycol and 1,2-propylene glycol.

Examples of the ketone-based solvent include chain ketone-based solvents such as methyl ethyl ketone and methyl isobutyl ketone, 2-heptanone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether, propylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [C], an alcohol-based solvent, an ether-based solvent, or an ester-based solvent is preferable, a monoalcohol-based solvent, a polyhydric alcohol partial ether-based solvent, or a polyhydric alcohol partial ether carboxylate-based solvent is more preferable, and 4-methyl-2-pentanol, propylene glycol monomethyl ether, or propylene glycol monomethyl ether acetate is still more preferable.

The lower limit of the content ratio of the solvent [C] in the composition for forming a resist underlayer film is preferably 50% by mass, more preferably 60% by mass, and still more preferably 70% by mass. The upper limit of the content ratio is preferably 99.99% by mass, and more preferably 99.9% by mass.

### [Optional Component]

The composition for forming a resist underlayer film may include an optional component as long as the effect of the composition is not impaired. Examples of the optional component include a crosslinking agent, an acid diffusion controlling agent, a polymer different from the polymer [A], a surfactant, and an acid generator (as a low-molecular form that does not bond to a polymer). The optional component may be used singly or two or more kinds thereof may be used in combination.

### (Crosslinking Agent [D])

The type of the crosslinking agent [D] is not particularly limited, and a publicly known crosslinking agent can be freely selected and used. Preferably, at least one selected from polyfunctional (meth)acrylates, cyclic ether-containing compounds, glycolurils, diisocyanates, melamines, benzoguanamines, polynuclear phenols, polyfunctional thiol compounds, polysulfide compounds, and sulfide compounds is preferably used as the crosslinking agent. When the composition contains the crosslinking agent [D], crosslinking of the polymer [A] can be advanced, and the solvent resistance of the resist underlayer film can be improved.

The polyfunctional (meth)acrylate is not particularly limited as long as it is a compound having two or more (meth)acryloyl groups, and examples thereof include a polyfunctional (meth)acrylate obtained by reacting an aliphatic polyhydroxy compound with (meth)acrylic acid, a caprolactone-modified polyfunctional (meth)acrylate, an alkylene oxide-modified polyfunctional (meth)acrylate, a polyfunctional urethane (meth)acrylate obtained by reacting a (meth)acrylate having a hydroxy group with a polyfunctional isocyanate, and a polyfunctional (meth)acrylate having a carboxyl group obtained by reacting a (meth)acrylate having a hydroxy group with an acid anhydride.

Specifically, examples of the polyfunctional (meth)acrylate include trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, glycerin tri(meth)acrylate, tris(2-hydroxyethyl) isocyanurate tri(meth)acrylate, ethylene glycol di(meth)acrylate, 1,3-butanediol di(meth)acrylate, 1,4-butanediol di(meth)acrylate, 1,6-hexanediol di(meth)acrylate, neopentyl glycol di(meth)acrylate, diethylene glycol di(meth)acrylate, triethylene glycol di(meth)acrylate, dipropylene glycol di(meth)acrylate, and bis(2-hydroxyethyl) isocyanurate di(meth)acrylate.

Examples of the cyclic ether-containing compound include oxiranyl group-containing compounds such as 1,6-hexanediol diglycidyl ether, 3′,4′-epoxycyclohexenylmethyl-3′,4′-epoxycyclohexenecarboxylate, vinylcyclohexene monooxide 1,2-epoxy-4-vinylcyclohexene, and 1,2:8,9 diepoxylimonene; and oxetanyl group-containing compounds such as 3-ethyl-3-hydroxymethyloxetane, 2-ethylhexyloxetane, xylylene bisoxetane, and 3-ethyl-3{[(3-ethyloxetan-3-yl)methoxy]methyl}oxetane. These cyclic ether-containing compounds can be used singly, or two or more types thereof may be used in combination.

Examples of the glycolurils include compounds derived from tetramethylolglycoluril, tetramethoxyglycoluril, tetramethoxymethylglycoluril, and tetramethylolglycoluril through methoxymethylation of 1 to 4 methylol groups thereof, or mixtures of the compounds, compounds derived from tetramethylolglycoluril through acyloxymethylation of 1 to 4 methylol groups thereof, and glycidylglycolurils.

Examples of the glycidylglycolurils include 1-glycidylglycoluril, 1,3-diglycidylglycoluril, 1,4-diglycidylglycoluril, 1,6-diglycidylglycoluril, 1,3,4-triglycidylglycoluril, 1,3,4,6-tetraglycidylglycoluril, 1-glycidyl-3a-methylglycoluril, 1-glycidyl-6a-methylglycoluril, 1,3-diglycidyl-3a-methylglycoluril, 1,4-diglycidyl-3a-methylglycoluril, 1,6-diglycidyl-3a-methylglycoluril, 1,3,4-triglycidyl-3a-methylglycoluril, 1,3,4-triglycidyl-6a-methyglycoluril, 1,3,4,6-tetraglycidyl-3a-methylglycoluril, 1-glycidyl-3a,6a-dimethylglycoluril, 1,3-diglycidyl-3a,6a-dimethylglycoluril, 1,4-diglycidyl-3a,6a-dimethylglycoluril, 1,6-diglycidyl-3a,6a-dimethylglycoluril, 1,3,4-triglycidyl-3a,6a-dimethylglycoluril, 1,3,4,6-tetraglycidyl-3a,6a-dimethylglycoluril, 1-glycidyl-3a,6a-diphenylglycoluril, 1,3-diglycidyl-3a,6a-diphenylglycoluril, 1,4-diglycidyl-3a,6a-diphenylglycoluril, 1,6-diglycidyl-3a,6a-diphenylglycoluril, 1,3,4-triglycidyl-3a,6a-diphenylglycoluril, and 1,3,4,6-tetraglycidyl-3a,6a-diphenylglycoluril. These glycolurils can be used singly, or two or more types thereof may be used in combination.

Examples of the diisocyanates include 2,3-tolylenediisocyanate, 2,4-tolylenediisocyanate, 3,4-tolylenediisocyanate, 3,5-tolylenediisocyanate, 4,4′-diphenylmethanediisocyanate, hexamethylenediisocyanate, and 1,4-cyclohexanediisocyanate.

Examples of the melamines include melamine, monomethylolmelamine, dimethylolmelamine, trimethylolmelamine, tetramethylolmelamine, pentamethylolmelamine, hexamethylolmelamine, monobutylolmelamine, dibutylolmelamine, tributylolmelamine, tetrabutylolmelamine, pentabutylolmelamine, and hexabthyolmelamine, and alkylated derivatives of these methylolmelamines or butylolmelamines. These melamines can be used singly, or two or more types thereof may be used in combination.

Examples of the benzoguanamines include benzoguanamine in which amino groups are modified with four alkoxymethyl groups (alkoxymethylol groups) (tetraalkoxymethylbenzoguanamines (tetraalkoxymethylolbenzoguanamines)), such as tetramethoxymethylbenzoguanamine;
benzoguanamine in which amino groups are modified with four groups in total of alkoxymethyl groups (especially, methoxymethyl groups) and hydroxymethyl groups (methylol groups);
benzoguanamine having amino groups modified with three or less alkoxymethyl groups (especially, methoxymethyl groups); and
benzoguanamine in which amino groups are modified with three or less groups in total of alkoxymethyl groups (especially, methoxymethyl groups) and hydroxymethyl groups.

These benzoguanamines can be used singly, or two or more types thereof may be used in combination.

Examples of the polynuclear phenols include binuclear phenols such as 4,4′-biphenyldiol, 4,4′-methylenebisphenol, 4,4′-ethylidenebisphenol, and bisphenol A; trinuclear phenols such as 4,4′,4″-methylidenetrisphenol, 4,4′-(1-(4-(1-(4-hydroxyphenyl)-1-methylethyl)phenyl)ethylidene)bisphenol, and 4,4′-(1-(4-(1-(4-hydroxy-3,5-bis(methoxymethyl)phenyl)-1-methylethyl)phenyl)ethylidene)bis(2,6-bis(methoxymethyl)phenol); and polyphenols such as novolac. These polynuclear phenols can be used singly, or two or more types thereof may be used in combination.

The polyfunctional thiol compound is a compound having two or more mercapto groups in one molecule, and specifically, examples thereof include compounds having two mercapto groups such as
1,2-ethanedithiol, 1,3-propanedithiol, 1,4-butanedithiol, 2,3-butanedithiol, 1,5-pentanedithiol, 1,6-hexanedithiol, 1,8-octanedithiol, 1,9-nonanedithiol, 2,3-dimercapto-1-propanol, dithioerythritol, 2,3-dimercaptosuccinic acid, 1,2-benzenedithiol, 1,2-benzenedimethanethiol, 1,3-benzenedithiol, 1,3-benzenedimethanethiol, 1,4-benzenedimethanethiol, 3,4-dimercaptooluene, 4-chloro-1,3-benzenedithiol, 2,4,6-trimethyl-1,3-benzenedimethanethiol, 4,4′-thiodiphenol, 2-hexylamino-4,6-dimercapto-1,3,5-triazine, 2-diethylamino-4,6-dimercapto-1,3,5-triazine, 2-cyclohexylamino-4,6-dimercapto-1,3,5-triazine, 2-di-n-butylamino-4,6-dimercapto-1,3,5-triazine, ethylene glycol bis(3-mercaptopropionate), butanediol bisthioglycolate, ethylene glycol bisthioglycolate, 2,5-dimercapto-1,3,4-thiadiazole, 2,2′-(ethylenedithio)diethanethiol, and 2,2-bis(2-hydroxy-3-mercaptopropoxyphenylpropane); compounds having three mercapto groups such as 1,2,6-hexanetrioltrithioglycolate, 1,3,5-trithiocyanuric acid, trimethylolpropane tris(3-mercaptopropionate), and trimethylolpropane tristhioglycolate; and compounds having 4 or more mercapto groups such as pentaerythritol tetrakis(2-mercaptoacetate), pentaerythritol tetrakis(2-mercaptopropionate) pentaerythritol tetrakis(3-mercaptopropionate), pentaerythritol tetrakis(3-mercaptobutyrate), and 1,3,5-tris(3-mercaptobutyryloxyethyl)-1,3,5-triazine-2,4,6 (1H, 3H, 5H)-trione. These polyfunctional thiol compounds can be used singly, or two or more types thereof may be used in combination.

When the composition for forming a resist underlayer film contains the crosslinking agent [D], the lower limit of the content of the crosslinking agent [D] is preferably 10% by mass, more preferably 15% by mass, and still more preferably 20% by mass based on the total mass of the polymer [A] and the crosslinking agent [D]. The upper limit of the content is preferably 70% by mass, more preferably 60% by mass, and still more preferably 55% by mass.

(Acid diffusion controlling agent [E])

The acid diffusion controlling agent [E] captures an acid and a cation. The acid diffusion controlling agent [E] may be used singly, or two or more types thereof may be used in combination.

Acid diffusion controlling agents [E] are classified into compounds having radiation reactivity and compounds having no radiation reactivity.

As the compounds having no radiation reactivity, basic compounds are preferable. Examples of the basic compounds include hydroxide compounds, carboxylate compounds, amine compounds, imine compounds, and amide compounds. More specific examples include primary to tertiary aliphatic amines, aromatic amines, heterocyclic amines, nitrogen-containing compounds having a carboxyl group, nitrogen-containing compounds having a sulfonyl group, nitrogen-containing compounds having a hydroxy group, nitrogen-containing compounds having a hydroxyphenyl group, alcoholic nitrogen-containing compounds, nitrogen-containing compounds having a carbamate group, amide compounds, and imide compounds. Among these, nitrogen-containing compounds having a carbamate group are preferable.

Further, the basic compounds may be Troger's bases; hindered amines such as diazabicycloundecene (DBU) and diazabicyclononene (DBM); and ionic quenchers such as tetrabutylammonium hydroxide (TBAH) and tetrabutylammonium lactate.

Examples of the primary aliphatic amines include ammonia, methylamine, ethylamine, n-propylamine, isopropylamine, n-butylamine, isobutylamine, sec-butylamine, tert-butylamine, pentylamine, tert-amylamine, cyclopentylamine, hexylamine, cyclohexylamine, heptylamine, octylamine, nonylamine, decylamine, dodecylamine, cetylamine, methylenediamine, ethylenediamine, and tetraethylenepentamine.

Examples of the secondary aliphatic amine include dimethylamine, diethylamine, di-n-propylamine, diisopropylamine, di-n-butylamine, diisobutylamine, di-sec-butylamine, dipentylamine, dicyclopentylamine, dihexylamine, dicyclohexylamine, diheptylamine, dioctylamine, dinonylamine, didecylamine, didodecylamine, dicetylamine, N,N-dimethylmethylenediamine, N,N-dimethylethylenediamine, and N,N-dimethyltetraethylenepentamine.

Examples of the tertiary aliphatic amine include trimethylamine, triethylamine, tri-n-propylamine, triisopropylamine, tri-n-butylamine, triisobutylamine, tri-sec-butylamine, tripentylamine, tricyclopentylamine, trihexylamine, tricyclohexylamine, triheptylamine, trioctylamine, trinonylamine, tridecylamine, tridodecylamine, tricetylamine, N,N,N′,N′-tetramethylmethylethylenediamine, N,N,N′,N′-tetramethylethylenediamine, and N,N,N′,N′-tetramethyltetraethylenepentamine.

Examples of the aromatic amine and heterocyclic amine include aniline derivatives such as aniline, N-methylaniline, N-ethylaniline, N-propylaniline, N,N-dimethylaniline, 2-methylaniline, 3-methylaniline, 4-methylaniline, ethylaniline, propylaniline, trimethylaniline, 2-nitroaniline, 3-nitroaniline, 4-nitroaniline, 2,4-dinitroaniline, 2,6-dinitroaniline, 3,5-dinitroaniline, and N,N-dimethyltoluidine; diphenyl(p-tolyl)amine; methyldiphenylamine; triphenylamine; phenylenediamine; naphthylamine; diaminonaphthalene; pyrrole derivatives such as pyrrole, 2H-pyrrole, 1-methylpyrrole, 2,4-dimethylpyrrole, 2,5-dimethylpyrrole, and N-methylpyrrole; oxazole derivatives such as oxazole and isoxazole; thiazole derivatives such as thiazole and isothiazole; imidazole derivatives such as imidazole, 4-methylimidazole, and 4-methyl-2-phenylimidazole; pyrazole derivatives; furazan derivatives; pyrroline derivatives such as pyrroline and 2-methyl-1-pyrroline; pyrrolidine derivatives such as pyrrolidine, N-methylpyrrolidine, pyrrolidinone, and N-methylpyrrolidone; imidazoline derivatives; imidazolidine derivatives; pyridine derivatives such as pyridine, methylpyridine, ethylpyridine, propylpyridine, butylpyridine, 4-(1-butylpentyl)pyridine, dimethylpyridine, trimethylpyridine, triethylpyridine, phenylpyridine, 3-methyl-2-phenylpyridine, 4-tert-butylpyridine, diphenylpyridine, benzylpyridine, methoxypyridine, butoxypyridine, dimethoxypyridine, 4-pyrrolidinopyridine, 2-(1-ethylpropyl)pyridine, aminopyridine, and dimethylaminopyridine; pyridazine derivatives; pyrimidine derivatives; pyrazine derivatives; pyrazoline derivatives; pyrazolidine derivatives; piperidine derivatives; piperazine derivatives; morpholine derivatives; indole derivatives; isoindole derivatives; 1H-indazole derivatives; indoline derivatives; quinoline derivatives such as quinoline and 3-quinolinecarbonitrile; isoquinoline derivatives; cinnoline derivatives; quinazoline derivatives; quinoxaline derivatives; phthalazine derivatives; purine derivatives; pteridine derivatives; carbazole derivatives; phenanthridine derivatives; acridine derivatives; phenazine derivatives; 1,10-phenanthroline derivatives; adenine derivatives; adenosine derivatives; guanine derivatives; guanosine derivatives; uracil derivatives; and uridine derivatives.

Examples of the nitrogen-containing compound having a carboxy group include aminobenzoic acid; indolecarboxylic acid; and amino acid derivatives such as nicotinic acid, alanine, arginine, aspartic acid, glutamic acid, glycine, histidine, isoleucine, glycylleucine, leucine, methionine, phenylalanine, threonine, lysine, 3-aminopyrazine-2-carboxylic acid, and methoxyalanine.

Examples of the nitrogen-containing compound having a sulfonyl group include 3-pyridinesulfonic acid and pyridinium p-toluenesulfonate.

Examples of the nitrogen-containing compound having a hydroxy group, the nitrogen-containing compound having a hydroxyphenyl group, and the alcoholic nitrogen-containing compound include 2-hydroxypyridine, aminocresol, 2,4-quinoline diol, 3-indole methanol hydrate, monoethanolamine, diethanolamine, triethanolamine, N-ethyldiethanolamine, N,N-diethylethanolamine, triisopropanolamine, 2,2′-iminodiethanol, 2-aminoethanol, 3-amino-1-propanol, 4-amino-1-butanol, 4-(2-hydroxyethyl)morpholine, 2-(2-hydroxyethyl)pyridine, 1-(2-hydroxyethyl)piperazine, 1-[2-(2-hydroxyethoxy)ethyl]piperazine, piperidineethanol, 1-(2-hydroxyethyl)pyrrolidine, 1-(2-hydroxyethyl)-2-pyrrolidinone, 3-piperidino-1,2-propanediol, 3-pyrrolidino-1,2-propanediol, 8-hydroxyjulolidine, 3-quinuclidinol, 3-tropanol, 1-methyl-2-pyrrolidine ethanol, 1-aziridine ethanol, N-(2-hydroxyethyl)phthalimide, and N-(2-hydroxyethyl)isonicotinamide.

Examples of the nitrogen-containing compound having a carbamate group include N-(tert-butoxycarbonyl)-L-alanine, N-(tert-butoxycarbonyl)-L-alanine methyl ester, (S)-(−)-2-(tert-butoxycarbonylamino)-3-cyclohexyl-1-propanol, (R)-(+)-2-(tert-butoxycarbonylamino)-3-methyl-1-butanol, (R)-(+)-2-(tert-butoxycarbonylamino)-3-phenylpropanol, (S)-(−)-2-(tert-butoxycarbonylamino)-3-phenylpropanol, (R)-(+)-2-(tert-butoxycarbonylamino)-3-phenyl-1-propanol, (S)-(−)-2-(tert-butoxycarbonylamino)-3-phenyl-1-propanol, (R)-(+)-2-(tert-butoxycarbonylamino)-1-propanol, (S)-(−)-2-(tert-butoxycarbonylamino)-1-propanol, N-(tert-butoxycarbonyl)-L-aspartic acid 4-benzyl ester, N-(tert-butoxycarbonyl)-O-benzyl-L-threonine, (R)-(+)-1-(tert-butoxycarbonyl)-2-tert-butyl-3-methyl-4-imidazolidinone, (S)-(−)-1-(tert-butoxycarbonyl)-2-tert-butyl-3-methyl-4-imidazolidinone, N-(tert-butoxycarbonyl)-3-cyclohexyl-L-alanine methyl ester, N-(tert-butoxycarbonyl)-L-cysteine methyl ester, N-(tert-butoxycarbonyl)ethanolamine, N-(tert-butoxycarbonyl)ethylenediamine, N-(tert-butoxycarbonyl)-D-glucosamine, Nα-(tert-butoxycarbonyl)-L-glutamine, 1-(tert-butoxycarbonyl) imidazole, N-(tert-butoxycarbonyl)-L-isoleucine, N-(tert-butoxycarbonyl)-L-isoleucine methyl ester, N-(tert-butoxycarbonyl)-L-leucinol, Nα-(tert-butoxycarbonyl)-L-lysine, N-(tert-butoxycarbonyl)-L-methionine, N-(tert-butoxycarbonyl)-3-(2-naphthyl)-L-alanine, N-(tert-butoxycarbonyl)-L-phenylalanine, N-(tert-butoxycarbonyl)-L-phenylalanine methyl ester, N-(tert-butoxycarbonyl)-D-prolinal, N-(tert-butoxycarbonyl)-L-proline, N-(tert-butoxycarbonyl)-L-proline-N′-methoxy-N′-methylamide, N-(tert-butoxycarbonyl)-1H-pyrazole-1-carboxyamidine, (S)-(−)-1-(tert-butoxycarbonyl)-2-pyrrolidinemethanol, (R)-(+)-1-(tert-butoxycarbonyl)-2-pyrrolidinemethanol, 1-(tert-butoxycarbonyl)-3-[4-(1-pyrrolyl)phenyl]-L-alanine, N-(tert-butoxycarbonyl)-L-serine, N-(tert-butoxycarbonyl)-L-serine methyl ester, N-(tert-butoxycarbonyl)-L-threonine, N-(tert-butoxycarbonyl)-p-toluenesulfonamide, N-(tert-butoxycarbonyl)-S-trityl-L-cysteine, Nα-(tert-butoxycarbonyl)-L-tryptophan, N-(tert-butoxycarbonyl)-L-tyrosine, N-(tert-butoxycarbonyl)-L-methyl ester, N-(tert-butoxycarbonyl)-L-valine, N-(tert-butoxycarbonyl)-tyrosine, N-(tert-butoxycarbonyl)-L-valine, N-(tert-butoxycarbonyl)-L-valine methyl ester, N-(tert-butoxycarbonyl)-L-valinol, tert-butyl N-(3-hydroxypropyl) carbamate, tert-butyl N-(6-aminohexyl) carbamate, tert-butyl carbamate, tert-butyl carbazate, tert-butyl N-(benzyloxy) carbamate, tert-butyl 4-benzyl-1-piperazinecarboxylate, tert-butyl (1S,4S)-(−)-2,5-diazabicyclo[2.2.1]heptane-2-carboxylate, tert-butyl N-(2,3-dihydroxypropyl) carbamate, tert-butyl(S)-(−)-4-formyl-2,2-dimethyl-3-oxazolidinecarboxylate, tert-butyl [R—(R*,S*)]—N-[2-hydroxy-2-(3-hydroxyphenyl)-1-methylethyl]carbamate, tert-butyl 4-oxo-1-piperidinecarboxylate, tert-butyl 1-pyrrolecarboxylate, tert-butyl 1-pyrrolidinecarboxylate, and tert-butyl (tetrahydro-2-oxo-3-furanyl) carbamate.

Examples of the amide compound include formamide, N-methylformamide, N,N-dimethylformamide, acetamide, N-methylacetamide, N,N-dimethylacetamide, propionamide, benzamide, and 1-cyclohexylpyrrolidone.

Examples of the imide compound include phthalimide, succinimide, and maleimide.

In addition, the compounds having radiation reactivity are classified into a compound that is degraded by radiation to lose acid diffusion controllability (radiation-degradable compound) and a compound that is generated by radiation to acquire acid diffusion controllability (radiation-generatable compound).

As the radiation-degradable compound, sulfonic acid salts and carboxylic acid salts each containing a radiation-degradable cation are preferred. As the sulfonic acid in the sulfonic acid salt, a weak acid is preferable, and a sulfonic acid that has a hydrocarbon group having 1 to 20 carbon atoms and containing no fluorine is more preferable. Examples of such a sulfonic acid include sulfonic acids such as alkyl sulfonic acids, benzene sulfonic acid, and 10-camphor sulfonic acid. As the carboxylic acid in the carboxylic acid salt, a weak acid is preferable, and a carboxylic acid having 1 to 20 carbon atoms is more preferable. Examples of such a carboxylic acid include carboxylic acids such as formic acid, acetic acid, propionic acid, tartaric acid, succinic acid, cyclohexylcarboxylic acid, benzoic acid, and salicylic acid. As the radiation-degradable cation in the carboxylic acid salt of the radiation-degradable cation, an onium cation is preferable, and examples of the onium cation include an iodonium cation and a sulfonium cation.

As the radiation-generatable compound, a compound that generates a base through exposure to light (radiation-sensitive base generating agent) is preferable, and a nitrogen-containing organic compound that generates an amino group is more preferable.

Examples of the radiation-sensitive base generating agent include the compounds described in JP-A-4-151156, JP-A-4-162040, JP-A-5-197148, JP-A-5-5995, JP-A-6-194834, JP-A-8-146608, JP-A-10-83079, and European patent No. 622682.

Examples of the radiation-sensitive base generating agent include a compound containing a carbamate group (urethane linkage), a compound containing an acyloxyimino group, an ionic compound (anion-cation complex), and a compound containing a carbamoyloxyimino group, and a compound containing a carbamate group (urethane linkage), a compound containing an acyloxyimino group, and an ionic compound (anion-cation complex) are preferable.

Furthermore, as the radiation-sensitive base generating agent, a compound having a ring structure in the molecule is preferable. Examples of the ring structure include benzene, naphthalene, anthracene, xanthone, thioxanthone, anthraquinone, and fluorene.

Examples of the radiation-sensitive base generating agent include 2-nitrobenzylcarbamate, 2,5-dinitrobenzylcyclohexylcarbamate, N-cyclohexyl-4-methylphenylsulfonamide, and 1,1-dimethyl-2-phenylethyl-N-isopropylcarbamate.

When the composition for forming a resist underlayer film contains the acid diffusion controlling agent [E], the lower limit of the content of the acid diffusion controlling agent [E] is preferably 0.1 parts by mass, more preferably 1 part by mass, and still more preferably 3 parts by mass per 100 parts by mass of the polymer [A]. The upper limit of the content is preferably 50 parts by mass, more preferably 40 parts by mass, and still more preferably 30 parts by mass.

[Method for Preparing Composition for Forming Resist Underlayer Film]

The composition for forming a resist underlayer film can be prepared by mixing the polymer [A], the solvent [C] and, as necessary, an optional component in a prescribed ratio and preferably filtering the resulting mixture through a membrane filter having a pore size of 0.5 μm or less, or the like.

### [Silicon-Containing Film Forming Step]

In this step performed before the application step (I), a silicon-containing film is formed directly or indirectly on a substrate.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The silicon-containing film can be formed by, for example, application, chemical vapor deposition (CVD), atomic layer deposition (ALD), or the like of a composition for forming a silicon-containing film. Examples of a method for forming a silicon-containing film by application of a composition for forming a silicon-containing film include a method in which a coating film formed by applying a composition for forming a silicon-containing film directly or indirectly to the substrate is cured by exposure and/or heating. As a commercially available product of the composition for forming a silicon-containing film, for example, “NFC SOG01”, “NFC SOG04”, or “NFC SOG080” (all manufactured by JSR Corporation) can be used. By chemical vapor deposition (CVD) or atomic layer deposition (ALD), a silicon oxide film, a silicon nitride film, a silicon oxynitride film, or an amorphous silicon film can be formed.

Examples of the radiation to be used for the exposure include electromagnetic waves such as visible rays, ultraviolet rays, far ultraviolet rays, X-rays, and y-rays and corpuscular rays such as electron beam, molecular beams, and ion beams.

The lower limit of the temperature in heating the coating film is preferably 90° C., more preferably 150° C., and still more preferably 200° C. The upper limit of the temperature is preferably 550° C., more preferably 450° C., and still more preferably 300° C.

The lower limit of the average thickness of the silicon-containing film is preferably 1 nm, more preferably 10 nm, and still more preferably 20 nm. The upper limit is preferably 20,000 nm, more preferably 1,000 nm, and still more preferably 100 nm. The average thickness of the silicon-containing film can be measured in the same manner as for the average thickness of the resist underlayer film.

Examples of a case where the silicon-containing film is formed indirectly on the substrate include a case where the silicon-containing film is formed on a low dielectric insulating film or an organic underlayer film formed on the substrate.

### [Application Step (I)]

In this step, a composition for forming a resist underlayer film is applied to the silicon-containing film formed on the substrate. The method of the application of the composition for forming a resist underlayer film is not particularly limited, and the application can be performed by an appropriate method such as spin coating, cast coating, or roll coating. As a result, a coating film is formed, and volatilization of the solvent [C] or the like occurs, so that a resist underlayer film is formed.

When the composition for forming a resist underlayer film is applied directly to the substrate, the silicon-containing film formation step may be omitted.

Next, the coating film formed by the application is heated. The formation of the resist underlayer film is promoted by heating the coating film. More specifically, volatilization or the like of the solvent [C] is promoted by heating the coating film.

The heating of the coating film may be performed either in the air atmosphere or in a nitrogen atmosphere. The lower limit of the heating temperature is preferably 100° C., more preferably 150° C., and still more preferably 200° C. The upper limit of the heating temperature is preferably 400° C., more preferably 350° C., and still more preferably 280° C. The lower limit of the heating time is preferably 15 seconds, and more preferably 30 seconds. The upper limit of the time is preferably 1,200 seconds, and more preferably 600 seconds.

The lower limit of the average thickness of the resist underlayer film to be formed is preferably 0.5 nm, more preferably 1 nm, and still more preferably 2 nm. The upper limit of the average thickness is 6 nm, preferably 5.5 nm, more preferably 5 nm, still more preferably 4.5 nm, and particularly preferably 4 nm. The average thickness is measured as described in Examples.

### [Application Step (II)]

In this step, a composition for forming a resist film is formed on the resist underlayer film formed by the step of applying a composition for forming a resist underlayer film. The method of applying the composition for forming a resist film is not particularly limited, and examples thereof include a spin coating method.

Describing this step more in detail, for example, a resist composition is applied such that a resist film formed comes to have a prescribed thickness, and then prebaking (hereinafter also referred to as “PB”) is performed to volatilize the solvent in the coating film. As a result, a resist film is formed.

The PB temperature and the PB time may be appropriately determined according to the type and the like of the composition for forming a resist film to be used. The lower limit of the PB temperature is preferably 30° C., and more preferably 50° C. The upper limit of the PB temperature is preferably 200° C., and more preferably 150° C. The lower limit of the PB time is preferably 10 seconds, and more preferably 30 seconds. The upper limit of the PB time is preferably 600 seconds, and more preferably 300 seconds.

Examples of the composition for forming a resist film to be used in this step include a positive or negative chemically amplified resist composition containing a radiation-sensitive acid generating agent, a positive resist composition containing an alkali-soluble resin and a quinonediazide-based photosensitizer, a negative resist composition containing an alkali-soluble resin and a crosslinking agent, and a metal-containing resist composition containing a metal such as tin, zirconium or hafnium.

### [Exposure Step]

In this step, a resist film formed in the step of applying a composition for forming a resist film is exposed to radiation.

Radiation to be used for the exposure can be appropriately selected according to the type or the like of the composition for forming a resist film to be used. Examples thereof include electromagnetic rays such as visible rays, ultraviolet rays, far-ultraviolet, X-rays, and y-rays and corpuscular rays such as electron beam, molecular beams, and ion beams. Among these, far-ultraviolet rays are preferable, and KrF excimer laser light (wavelength: 248 nm), ArF excimer laser light (wavelength: 193 nm), F₂ excimer laser light (wavelength: 157 nm), Kr₂ excimer laser light (wavelength: 147 nm), ArKr excimer laser light (wavelength: 134 nm) or extreme ultraviolet rays (wavelength: 13.5 nm, etc., also referred to as “EUV”) are more preferred, and ArF excimer laser light or EUV is even more preferred. Further, the exposure conditions can be determined as appropriate depending on the type of resist film forming composition used.

In this step, post exposure baking (hereinafter, also referred to as “PEB”) can be performed after the exposure in order to improve the resist film performance such as resolution, pattern profile, and developability. The PEB temperature and the PEB time may be appropriately determined according to the type and the like of the composition for forming a resist film to be used. The lower limit of the PEB temperature is preferably 50° C., and more preferably 70° C. The upper limit of the PEB temperature is preferably 200° C., and more preferably 150° C. The lower limit of the PEB time is preferably 10 seconds, and more preferably 30 seconds. The upper limit of the PEB time is preferably 600 seconds, and more preferably 300 seconds.

### [Development Step]

In this step, the exposed resist film is developed. At this time, a part of the resist underlayer film may also be developed. Examples of the developer to be used for the development include an aqueous alkaline solution (alkaline developer) and an organic solvent-containing solution (organic solvent developer).

The basic solution for the alkali development is not particularly limited, and a publicly known basic solution can be used. Examples of the basic solution for the alkali development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene. Among them, the aqueous TMAH solution is preferable, and a 2.38% by mass aqueous TMAH solution is more preferable.

Examples of the organic solvent developer in the case of performing organic solvent development include the same as those disclosed as the examples of the solvent [C] described above. As the organic solvent developer, an ester-based solvent, an ether-based solvent, an alcohol-based solvent, a ketone-based solvent and/or a hydrocarbon-based solvent is preferable, a ketone-based solvent is more preferable, and 2-heptanone is particularly preferable.

In this step, washing and/or drying may be performed after the development.

### [Etching Step]

In this step, etching is performed using the resist pattern (and the resist underlayer film pattern) as a mask. The number of times of the etching may be once. Alternatively, etching may be performed a plurality of times, that is, etching may be sequentially performed using a pattern obtained by etching as a mask. From the viewpoint of obtaining a pattern having a favorable shape, etching is preferably performed a plurality of times. When performed a plurality of times, etching is performed to the silicon-containing film, and the substrate sequentially in order. Examples of an etching method include dry etching and wet etching. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₈, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, NO, and BCl₃, and inert gases such as He, N₂ and Ar are used. These gases can also be mixed and used. When the substrate is etched using the pattern of the resist underlayer film as a mask, a fluorine-based gas is usually used.

When the silicon-containing film remains on the substrate or the like after the substrate pattern formation, the silicon-containing film can be removed by performing a removal step described later.

### <<Composition for Forming a Resist Underlayer Film>>

The composition for forming a resist underlayer film contains the polymer [A], and the solvent [C]. As such a composition for forming a resist underlayer film, the composition for forming a resist underlayer film to be used in the above-described method for manufacturing a semiconductor substrate can be suitably employed.

### EXAMPLES

Hereinafter, Examples are described. The following Examples merely illustrate typical Examples of the present disclosure, and the Examples should not be construed to narrow the scope of the present invention.

### [Weight-Average Molecular Weight (Mw)]

The Mw of a polymer (x-1) was measured by gel permeation chromatography (detector: differential refractometer) with monodisperse polystyrene standards using GPC columns (“G2000HXL”×2 and “G3000HXL”×1) manufactured by Tosoh Corporation under the following analysis conditions: flow rate: 1.0 mL/min; elution solvent: tetrahydrofuran; column temperature: 40° C.

### [Average Thickness of Film]

An average thickness of a film was determined as a value obtained by measuring the film thickness at arbitrary nine points at intervals of 5 cm including the center of the resist underlayer film using a spectroscopic ellipsometer (“M2000D” available from J. A. WOOLLAM Co.) and calculating the average value of the film thicknesses.

### <Synthesis of Polymer [A]>

The polymer [A] was synthesized by the following procedure. In the following formula, the content ratios (mol %) of repeating units denoted by x, y, and z are attached. In the following formulas, “Et” denotes an ethyl group, “Pr” denotes an n-propyl group, “tBu” denotes a t-butyl group, and “TPS” denotes triphenylsulfonium. The composition ratio was confirmed by ¹³C-NMR.

The respective monomers were combined and subjected to a copolymerization reaction in a tetrahydrofuran (THF) solvent, and the reaction products were crystallized in methanol, and washed repeatedly with hexane, then isolated, and dried. Thus, polymers (A-1 to A-20) having the compositions shown below were obtained. As to the composition of the obtained polymers, the weight average molecular weight (Mw) and the dispersion degree (Mw/Mn) were confirmed by GPC (solvent: THE, standard: polystyrene).
A-1; Mw: 9200, Mw/Mn: 1.80
A-2; Mw: 9100, Mw/Mn: 1.80
A-3; Mw: 9200, Mw/Mn: 1.80
A-4; Mw: 8900, Mw/Mn: 1.81
A-5; Mw: 9100, Mw/Mn: 1.82
A-6; Mw: 9000, Mw/Mn: 1.81
A-7; Mw: 9200, Mw/Mn: 1.80
A-8; Mw: 9000, Mw/Mn: 1.80
A-9; Mw: 8700, Mw/Mn: 1.81
A-10; Mw: 8900, Mw/Mn: 1.80
A-11; Mw: 9000, Mw/Mn: 1.82
A-12; Mw: 9100, Mw/Mn: 1.81
A-13; Mw: 9200, Mw/Mn: 1.80
A-14; Mw: 9000, Mw/Mn: 1.81
A-15; Mw: 8600, Mw/Mn: 1.79
A-16; Mw: 8800, Mw/Mn: 1.80
A-17; Mw: 8900, Mw/Mn: 1.81
A-18; Mw: 9200, Mw/Mn: 1.80
A-19; Mw: 9100, Mw/Mn: 1.80
A-20; Mw: 9000, Mw/Mn: 1.80

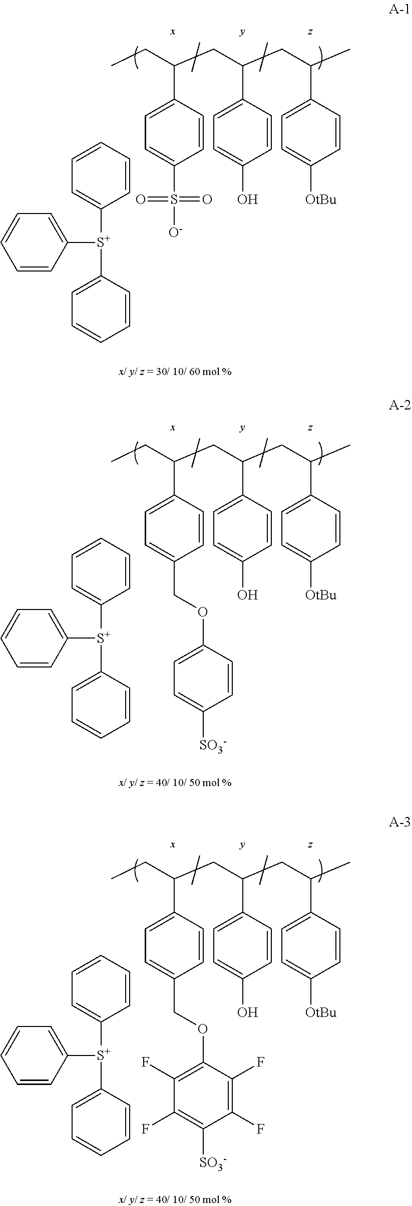

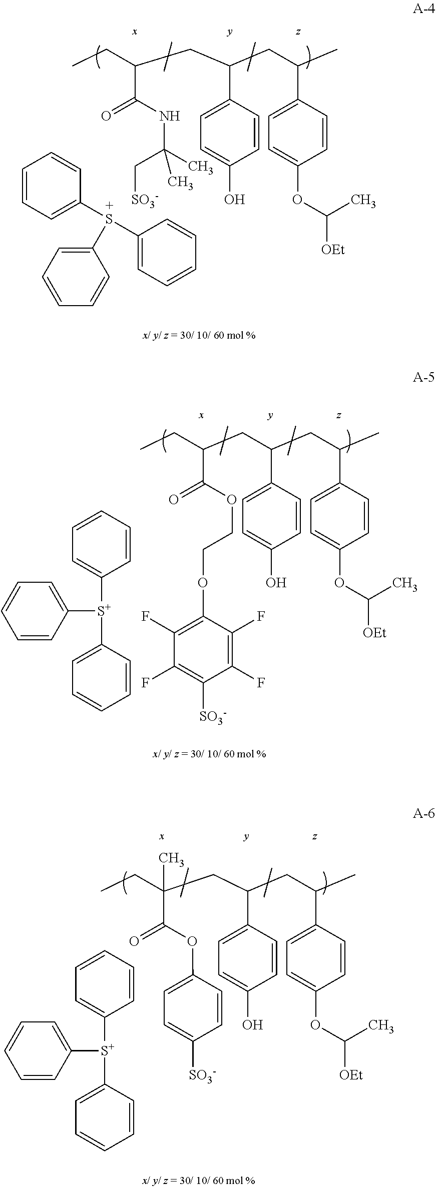

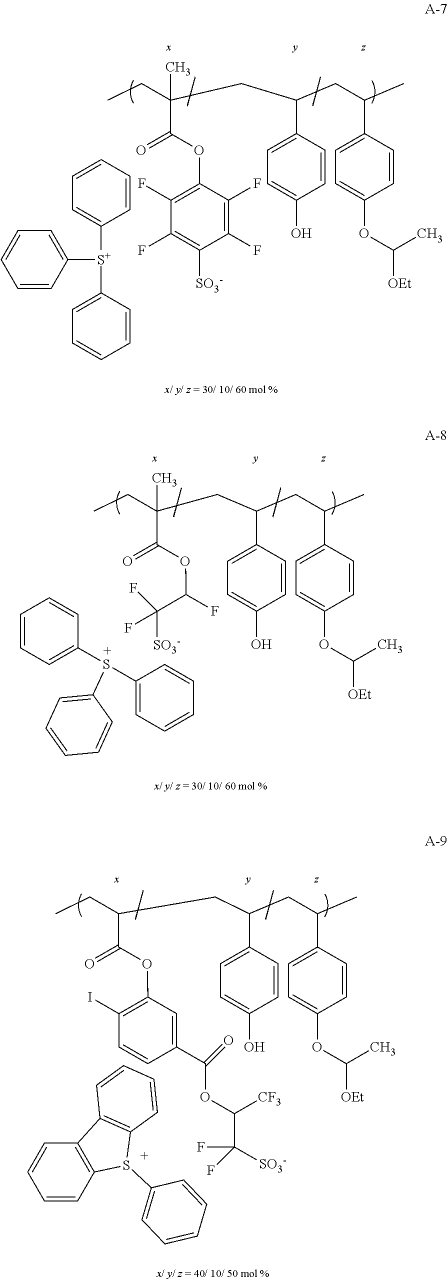

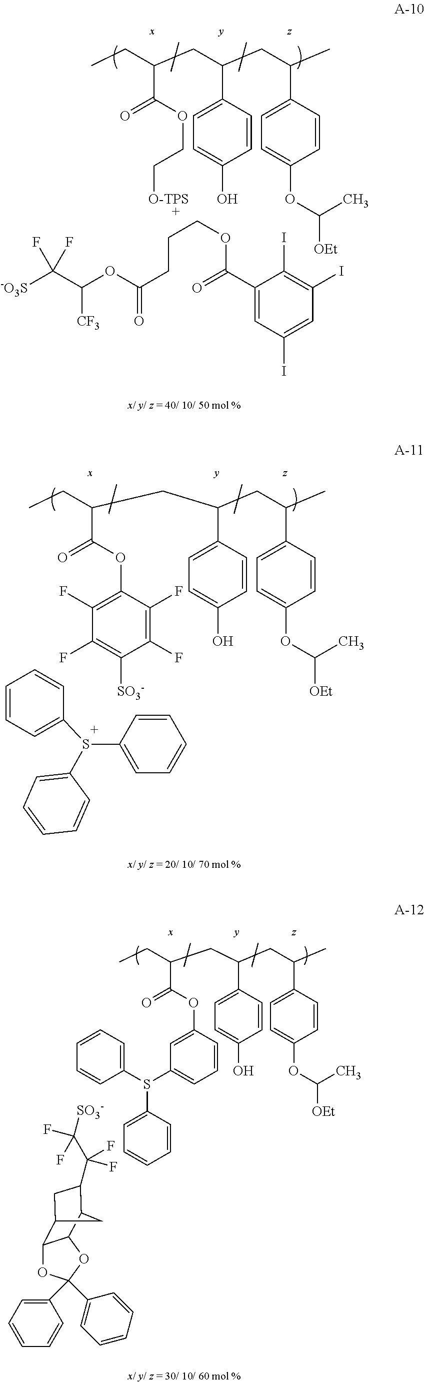

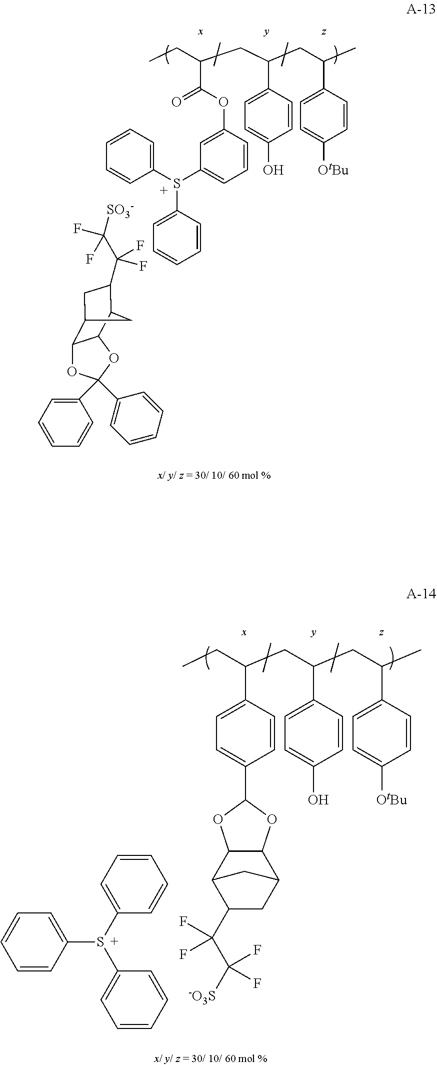

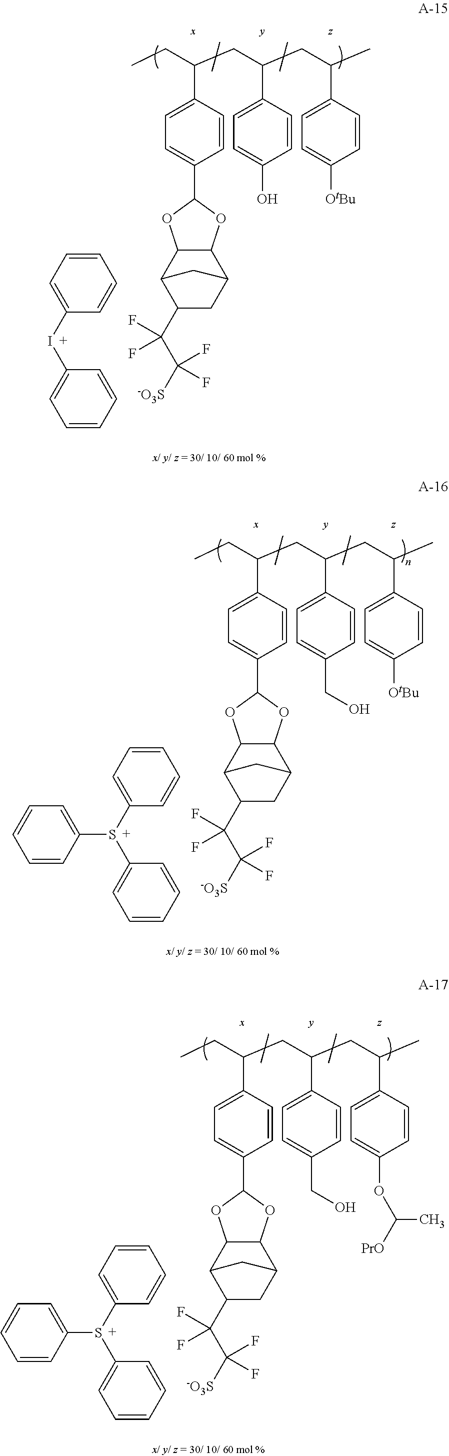

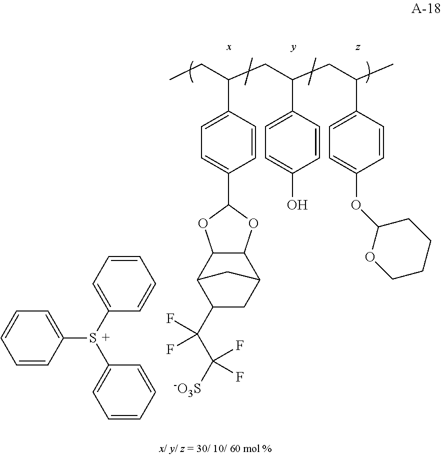

### <Synthesis of Polymer [B]>

The polymers represented by the following formulas (B-1), (B-2), and (B-3) (hereinafter also referred to as “polymers (B-1)” and the like) were each synthesized by the following procedure. In the following formulas, the number attached to each repeating unit represents the content ratio (mol %) of the repeating unit.

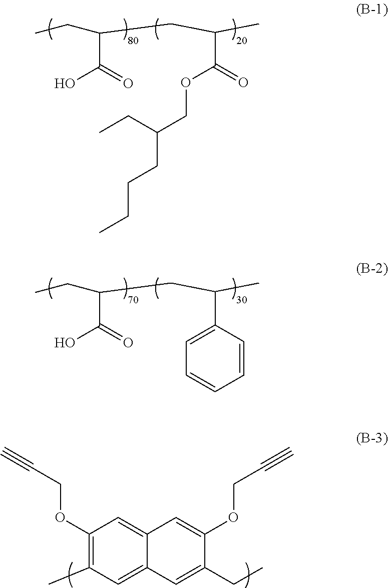

### [Synthesis Example 2-1] (Synthesis of Polymer (B-1))

63 g of acrylic acid, 36 g of 2-ethylhexyl acrylate, and 21.2 g of dimethyl 2,2′-azobis(2-methylpropionate) were added to prepare a monomer solution. In a nitrogen atmosphere, 300 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether, and methyl isobutyl ketone was removed by concentration under reduced pressure, affording a propylene glycol monomethyl ether solution of polymer (B-1). The Mw of the polymer (B-1) was 6,500.

### [Synthesis Example 2-2] (Synthesis of Polymer (B-2))

66 g of acrylic acid, 34 g of styrene, and 25.1 g of dimethyl 2,2′-azobis(2-methylpropionate) were added to prepare a monomer solution. In a nitrogen atmosphere, 300 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether, and methyl isobutyl ketone was removed by concentration under reduced pressure, affording a propylene glycol monomethyl ether solution of polymer (B-2). The Mw of the polymer (B-2) was 5,300.

### [Synthesis Example 2-3] (Synthesis of Polymer (B-3))

In a nitrogen atmosphere, 29.1 g of 2,7-dihydroxynaphthalene, 14.8 g of a 37% by mass formaldehyde solution, and 87.3 g of methyl isobutyl ketone were charged into a reaction and dissolved. After adding 1.0 g of p-toluenesulfonic acid monohydrate to the reaction vessel, and then the mixture was heated to 85° C. and reacted for 4 hours.

After completion of the reaction, the reaction solution was transferred to a separatory funnel, 200 g of methyl isobutyl ketone and 400 g of water were added thereto, and the organic phase was washed. After separating the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (b-3) having a repeating unit represented by formula (b-3). The Mw of the polymer (b-3) was 3,400.

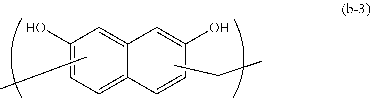

In a nitrogen atmosphere, 16.8 g of the polymer (b-3), 34.9 g of propargyl bromide, 90 g of methyl isobutyl ketone, and 45.0 g of methanol were added to a reaction vessel, and the mixture was stirred. Then, 106.9 g of a 25% by mass aqueous tetramethylammonium hydroxide solution was added thereto, and the mixture was reacted at 50° C. for 6 hours. The reaction solution was cooled to 30° C., and then 200.0 g of a 5% by mass aqueous oxalic acid solution was added. After removing the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (B-3) represented by the formula (B-3). The Mw of the polymer (B-3) was 4,500.

### <Preparation of Composition>

The polymers [A], the polymers [B], the solvents [C], and the crosslinking agents [D] used for the preparation of compositions are shown below.

### [Polymer [A]]

Polymers (A-1) to (A-20) synthesized above

### [Polymer [B]]

Polymers (B-1) to (B-3) synthesized above

### [Solvent [C]]

C-1: Propylene glycol monomethyl ether acetate
C-2: Propylene glycol monomethyl ether
C-3: Ethyl lactate
C-4: Diacetone alcohol

### [Crosslinking Agent [D]]

D-1: Compound represented by the following formula (D-1)
D-2: Compound represented by the following formula (D-2)

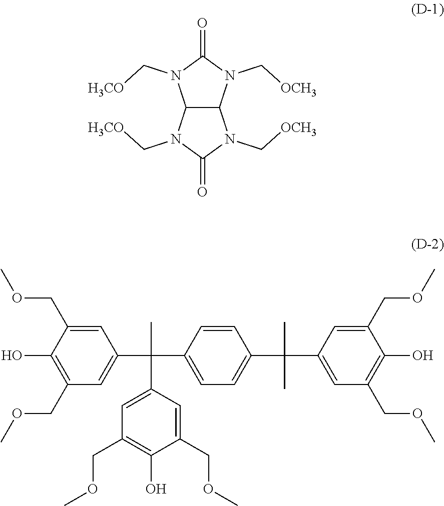

### Example 1

In 24000 parts by mass of (C-1) and 16000 parts by mass of (C-2) as the solvent [C] were dissolved 67 parts by mass of (A-1) as the polymer [A] and 33 parts by mass of (D-1) as the crosslinking agent [D]. The resulting solution was filtered through a polytetrafluoroethylene (PTFE) membrane filter having a pore size of 0.45 μm to prepare composition (J-1).

### Examples 2 to 28 and Comparative Examples 1 to 2

Compositions (J-2) to (J-28) and (CJ-1) to (CJ-2) were prepared in the same manner as in Example 1 except that the components of the types and contents shown in the following Table 1 were used. “−” in the columns [A], [B], and [D] in Table 1 each indicate that the corresponding component was not used.

TABLE 1

| | | | | | | | | Crosslinking | |
|---|---|---|---|---|---|---|---|---|---|
| | | Polymer [A] | | Polymer [B] | | Solvent [C] | | agent [D] | |
| | | | Content | | Content | | Content | | Content |
| | | | (parts | | (parts | | (parts | | (parts |
| | Composition | Type | by mass) | Type | by mass) | Type | by mass) | Type | by mass) |
| Example 1 | J-1 | A-1 | 67 | — | — | C-1/C-2 | 24000/16000 | D-1 | 33 |
| Example 2 | J-2 | A-2 | 67 | — | — | C-1/C-2 | 24000/16000 | D-2 | 33 |
| Example 3 | J-3 | A-3 | 67 | — | — | C-1/C-3 | 24000/16000 | D-2 | 33 |
| Example 4 | J-4 | A-4 | 67 | — | — | C-1/C-4 | 24000/16000 | D-2 | 33 |
| Example 5 | J-5 | A-5 | 67 | — | — | C-1/C-2 | 24000/16000 | D-2 | 33 |
| Example 6 | J-6 | A-6 | 67 | — | — | C-1/C-3 | 20000/20000 | D-1 | 33 |
| Example 7 | J-7 | A-7 | 67 | — | — | C-1/C-2 | 24000/16000 | D-2 | 33 |
| Example 8 | J-8 | A-8 | 67 | — | — | C-1/C-4 | 24000/16000 | D-2 | 33 |
| Example 9 | J-9 | A-9 | 67 | — | — | C-1/C-2 | 24000/16000 | D-2 | 33 |
| Example 10 | J-10 | A-10 | 67 | — | — | C-1/C-3 | 24000/16000 | D-2 | 33 |
| Example 11 | J-11 | A-11 | 67 | — | — | C-1/C-2 | 24000/16000 | D-2 | 33 |
| Example 12 | J-12 | A-12 | 67 | — | — | C-1/C-2 | 24000/16000 | D-2 | 33 |
| Example 13 | J-13 | A-13 | 67 | — | — | C-1/C-4 | 24000/16000 | D-2 | 33 |
| Example 14 | J-14 | A-14 | 67 | — | — | C-1/C-2 | 24000/16000 | D-2 | 33 |
| Example 15 | J-15 | A-15 | 67 | — | — | C-1/C-2 | 24000/16000 | D-2 | 33 |
| Example 16 | J-16 | A-16 | 67 | — | — | C-1/C-2 | 24000/16000 | D-2 | 33 |
| Example 17 | J-17 | A-17 | 67 | — | — | C-1/C-2 | 24000/16000 | D-2 | 33 |
| Example 18 | J-18 | A-18 | 67 | — | — | C-1/C-2 | 24000/16000 | D-2 | 33 |
| Example 19 | J-19 | A-19 | 67 | — | — | C-1/C-2 | 24000/16000 | D-2 | 33 |
| Example 20 | J-20 | A-20 | 67 | — | — | C-1/C-2 | 24000/16000 | D-2 | 33 |
| Example 21 | J-21 | A-3 | 50 | — | — | C-1/C-2 | 24000/16000 | D-2 | 50 |
| Example 22 | J-22 | A-9 | 50 | — | — | C-1/C-2 | 24000/16000 | D-2 | 50 |
| Example 23 | J-23 | A-11 | 50 | — | — | C-1/C-2 | 24000/16000 | D-2 | 50 |
| Example 24 | J-24 | A-12 | 67 | — | — | C-1/C-3 | 24000/16000 | D-2 | 50 |
| Example 25 | J-25 | A-13 | 67 | — | — | C-1/C-4 | 24000/16000 | D-2 | 50 |
| Example 26 | J-26 | A-14 | 70 | — | — | C-1/C-3 | 24000/16000 | D-2 | 30 |
| Example 27 | J-27 | A-15 | 70 | — | — | C-1/C-4 | 24000/16000 | D-2 | 30 |
| Example 28 | J-28 | A-19 | 75 | B-3 | 5 | C-1/C-2 | 20000/20000 | D-1 | 20 |
| Comparative | CJ-1 | — | — | B-1 | 67 | C-1/C-2 | 24000/16000 | D-2 | 33 |
| Example 1 | | | | | | | | | |
| Comparative | CJ-2 | — | — | B-2 | 67 | C-1/C-2 | 24000/16000 | D-2 | 33 |
| Example 2 | | | | | | | | | |

### <Evaluation>

Using the compositions for forming a resist underlayer film prepared as described above, the rectangularity of a resist pattern was evaluated by the following method. The evaluation results are given in the following Table 2.

### <Preparation of Resist Composition (R-1)>

Resist composition (R-1) was prepared by mixing 100 parts by mass of resin (r-1), 20 parts by mass of an acid generator (F-1), 50 mol % of an acid diffusion controlling agent (G-1) with respect to the acid generator (F-1), and 7700 parts by mass of propylene glycol monomethyl ether acetate and 3300 parts by mass of propylene glycol monomethyl ether as solvents, and filtering the mixture through a membrane filter having a pore size of 0.2 μm.

The resin (r-1) was a polymer in which the content ratios of repeating units derived from the following monomer (M-1) and monomer (M-2) were 50 mol % and 50 mol %, respectively, and had an Mw of 6,400 and an Mw/Mn of 1.50. As the acid generator (F-1) and the acid diffusion controlling agent (G-1), the following compounds were used.

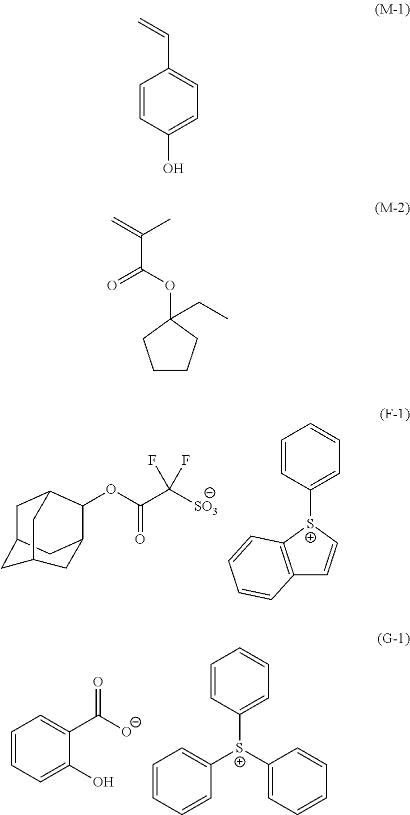

### [Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied a composition for forming a silicon-containing film (“NFC SOG080” manufactured by JSR Corporation), heated at 220° C. for 60 sec, and then cooled at 23° C. for 30 sec. Thus, a silicon-containing film having an average thickness of 20 nm was formed. To the silicon-containing film formed as described above was applied the composition for forming a resist underlayer film prepared above, heated at 250° C. for 60 sec, and then cooled at 23° C. for 30 sec. Thus, a resist underlayer film having an average thickness of 5 nm was formed. To the resist underlayer film formed as described above was applied a resist composition (R-1), heated at 130° C. for 60 sec, and then cooled at 23° C. for 30 sec. Thus, a resist film having an average thickness of 50 nm was formed. Next, the resist film was irradiated with extreme ultraviolet rays using an EUV scanner (“TWINSCAN NXE: 3300B”, available from ASML Co. (NA=0.3; Sigma=0.9; quadrupole illumination, with a 1:1 line and space mask having a line width of 26 nm in terms of a dimension on wafer)). After the irradiation with the extreme ultraviolet rays, the substrate was heated at 110° C. for 60 sec, followed by cooling at 23° C. for 60 sec. Thereafter, development was performed by a paddle method using a 2.38% by mass aqueous tetramethylammonium hydroxide solution (20° C. to 25° C.), followed by washing with water and drying, thereby affording a substrate for evaluation on which a resist pattern having 1:1 line and space with line width of 26 nm was formed. A scanning electron microscope (“SU8220” available from Hitachi High-Technologies Corporation) was used for length measurement and observation of the resist pattern of the substrate for evaluation. The pattern rectangularity was evaluated as “A” (good) when the cross-sectional shape of the pattern was rectangular, and “B” (poor) when trailing was present in the cross section of the pattern.

TABLE 2

| | | Resist | Resist pattern |
|---|---|---|---|
| | Composition | composition | rectangularity |
| Example 1 | J-1 | R-1 | A |
| Example 2 | J-2 | R-1 | A |
| Example 3 | J-3 | R-1 | A |
| Example 4 | J-4 | R-1 | A |
| Example 5 | J-5 | R-1 | A |
| Example 6 | J-6 | R-1 | A |
| Example 7 | J-7 | R-1 | A |
| Example 8 | J-8 | R-1 | A |
| Example 9 | J-9 | R-1 | A |
| Example 10 | J-10 | R-1 | A |
| Example 11 | J-11 | R-1 | A |
| Example 12 | J-12 | R-1 | A |
| Example 13 | J-13 | R-1 | A |
| Example 14 | J-14 | R-1 | A |
| Example 15 | J-15 | R-1 | A |
| Example 16 | J-16 | R-1 | A |
| Example 17 | J-17 | R-1 | A |
| Example 18 | J-18 | R-1 | A |
| Example 19 | J-19 | R-1 | A |
| Example 20 | J-20 | R-1 | A |
| Example 21 | J-21 | R-1 | A |
| Example 22 | J-22 | R-1 | A |
| Example 23 | J-23 | R-1 | A |
| Example 24 | J-24 | R-1 | A |
| Example 25 | J-25 | R-1 | A |
| Example 26 | J-26 | R-1 | A |
| Example 27 | J-27 | R-1 | A |
| Example 28 | J-28 | R-1 | A |
| Comparative | CJ-1 | R-1 | B |
| Example 1 | | | |
| Comparative | CJ-2 | R-1 | B |
| Example 2 | | | |

### <Evaluation>

Using the compositions for forming a resist underlayer film prepared as described above, the rectangularity of a resist pattern was evaluated by the following method. The evaluation results are given in the following Table 3.

### <Preparation of Resist Composition (R-2)>

### [Synthesis of Compound]

The compound (S-1) to be used for the preparation of a resist composition (R-2) was synthesized by the following procedure. In a reaction vessel, 6.5 parts by mass of isopropyltin trichloride was added while stirring 150 mL of a 0.5 N aqueous sodium hydroxide solution, and a reaction was carried out for 2 hours. The precipitate formed was collected by filtration, washed twice with 50 parts by mass of water, and then dried, affording a compound (S-1). The compound (S-1) was an oxidized hydroxide product of a hydrolysate of isopropyltin trichloride (the oxidized hydroxide product contained i-PrSnO_{(3/2-x/2)} (OH)ₓ (0<x<3) as a structural unit).

2 parts by mass of the compound (S-1) synthesized above and 98 parts by mass of propylene glycol monoethyl ether were mixed, and the resulting mixture was subjected to removal of residual water with activated 4 Å molecular sieve, and then filtered through a filter having a pore size of 0.2 μm. Thus, a resist composition (R-2) was prepared.

### [Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied the composition for forming a resist underlayer film prepared above, heated at 220° C. for 60 sec, and then cooled at 23° C. for 30 sec. Thus, a resist underlayer film having an average thickness of 5 nm was formed. To the resist underlayer film was applied the resist composition (R-2) by the spin coating method using the spin coater described above, and after a lapse of a prescribed time, heated at 90° C. for 60 sec, and then cooled at 23° C. for 30 sec. Thus, a resist film having an average thickness of 35 nm was formed. The resist film was exposed to light using an EUV scanner (“TWINSCAN NXE: 3300B”, available from ASML Co. (NA=0.3; Sigma=0.9; quadrupole illumination, with a 1:1 line and space mask having a line width of 25 nm in terms of a dimension on wafer)). After the exposure, the substrate was heated at 110° C. for 60 sec, and subsequently cooled at 23° C. for 60 sec. Thereafter, development was performed by a paddle method using 2-heptanone (20 to 25° C.), and then dried, affording a substrate for evaluation on which a 1:1 line-and-space resist pattern with a line width of 25 nm was formed. A scanning electron microscope (“CG-6300” available from Hitachi High-Tech Corporation) was used for length measurement and observation of the resist pattern of the substrate for evaluation. The pattern rectangularity was evaluated as “A” (good) when the cross-sectional shape of the pattern was rectangular, and “B” (poor) when trailing was present in the cross section of the pattern.

TABLE 3

| | | Resist | Resist pattern |
|---|---|---|---|
| | Composition | composition | rectangularity |
| Example 1 | J-1 | R-2 | A |
| Example 2 | J-2 | R-2 | A |
| Example 3 | J-3 | R-2 | A |
| Example 4 | J-4 | R-2 | A |
| Example 5 | J-5 | R-2 | A |
| Example 6 | J-6 | R-2 | A |
| Example 7 | J-7 | R-2 | A |
| Example 8 | J-8 | R-2 | A |
| Example 9 | J-9 | R-2 | A |
| Example 10 | J-10 | R-2 | A |
| Example 11 | J-11 | R-2 | A |
| Example 12 | J-12 | R-2 | A |
| Example 13 | J-13 | R-2 | A |
| Example 14 | J-14 | R-2 | A |
| Example 15 | J-15 | R-2 | A |
| Example 16 | J-16 | R-2 | A |
| Example 17 | J-17 | R-2 | A |
| Example 18 | J-18 | R-2 | A |
| Example 19 | J-19 | R-2 | A |
| Example 20 | J-20 | R-2 | A |
| Example 21 | J-21 | R-2 | A |
| Example 22 | J-22 | R-2 | A |
| Example 23 | J-23 | R-2 | A |
| Example 24 | J-24 | R-2 | A |
| Example 25 | J-25 | R-2 | A |
| Example 26 | J-26 | R-2 | A |
| Example 27 | J-27 | R-2 | A |
| Example 28 | J-28 | R-2 | A |
| Comparative | CJ-1 | R-2 | B |
| Example 1 | | | |
| Comparative | CJ-2 | R-2 | B |
| Example 2 | | | |

As can be seen from the results shown in Tables 2 and 3, the resist underlayer films formed from the compositions for forming a resist underlayer film of Examples were superior in pattern rectangularity to the resist underlayer films formed from the compositions for forming a resist underlayer film of Comparative Examples.

By the method for manufacturing a semiconductor substrate of the present disclosure, it is possible to efficiently manufacture a semiconductor substrate because of using a composition for forming a resist underlayer film capable of forming a resist underlayer film superior in pattern rectangularity. When the composition for forming a resist underlayer film of the present disclosure is used, a film superior in pattern rectangularity can be formed. Therefore, they can suitably be used for, for example, producing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
applying a composition for forming a resist underlayer film directly or indirectly to a substrate to form a resist underlayer film;
applying a composition for forming a resist film to the resist underlayer film to form a resist film;
exposing the resist film to radiation; and
developing at least the exposed resist film,
wherein the composition for forming a resist underlayer film comprises:
a polymer comprising a repeating unit (1) which comprises an organic sulfonic acid anion moiety and an onium cation moiety; and
a solvent.

2. The method according to claim 1, wherein the repeating unit (1) is represented by at least one selected from the group consisting of formula (1-1) and formula (1-2), 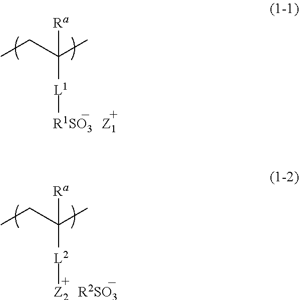
wherein, in the formulae (1-1) and (1-2), each R^{a} is independently a hydrogen atom or a substituted or unsubstituted monovalent hydrocarbon group having 1 to 20 carbon atoms,
in the formula (1-1), L¹ is a divalent linking group; R¹ is a single bond or a divalent organic group having 1 to 40 carbon atoms; and Zit is a monovalent onium cation,
in the formula (1-2), L² is a divalent linking group; Z₂⁺ is a monovalent group having a monovalent onium cation structure; and R² is a monovalent organic group having 1 to 40 carbon atoms.

3. The method according to claim 1, wherein the composition for forming a resist film comprises a metal.

4. The method according to claim 1, wherein the resist underlayer film has a film thickness of 6 nm or less.

5. The method according to claim 1, wherein the radiation is an electron beam or extreme ultraviolet rays.

6. A composition for forming a resist underlayer film, comprising:
a polymer comprising a repeating unit (1) which comprises an organic sulfonic acid anion moiety and an onium cation moiety; and
a solvent.

7. The composition according to claim 6, wherein the repeating unit (1) is represented by at least one selected from the group consisting of formula (1-1) and formula (1-2), 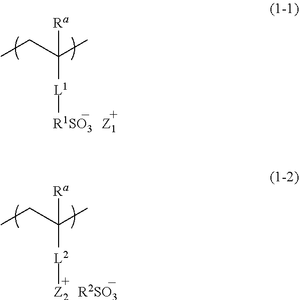
wherein, in the formulae (1-1) and (1-2), each R^{a} is independently a hydrogen atom or a substituted or unsubstituted monovalent hydrocarbon group having 1 to 20 carbon atoms,
in the formula (1-1), L¹ is a divalent linking group; R¹ is a single bond or a divalent organic group having 1 to 40 carbon atoms; and Z₁⁺ is a monovalent onium cation,
in the formula (1-2), L² is a divalent linking group; Z₂⁺ is a monovalent group having a monovalent onium cation structure; and R² is a monovalent organic group having 1 to 40 carbon atoms.

8. The composition according to claim 7, wherein L¹ in the formula (1-1) and L² in the formula (1-2) each comprise a divalent aromatic ring.

9. The composition according to claim 6, wherein the polymer further comprises at least one selected from the group consisting of a repeating unit comprising a phenolic hydroxy group and a repeating unit comprising a group that is capable of generating a phenolic hydroxy group by an action of an acid.

10. The composition according to claim 6, the polymer further comprises a repeating unit having an oxazoline structure, an ethylene structure, an ethyne structure, an oxirane structure, or combinations thereof.

11. The composition according to claim 6, wherein a content of the repeating unit (1) in the polymer relative to 100 mol % of all repeating units constituting the polymer is from 10 to 80 mol %.

12. The composition according to claim 6, wherein the composition is suitable for forming an underlayer film of a resist film to be exposed to extreme ultraviolet rays.

13. The composition according to claim 6, wherein the composition is suitable for forming an underlayer film of a resist film containing a metal.

14. The composition according to claim 6, wherein the composition is suitable for forming a resist underlayer film having a film thickness of 6 nm or less.

15. The composition according to claim 6, further comprising a crosslinking agent.
